(19) United States
(12) Patent Application Publication
(10) Pub. No.: US 2025/0248043 A1
(43) Pub. Date: Jul. 31, 2025

(54) SEMICONDUCTOR DEVICE AND DATA STORAGE SYSTEM INCLUDING THE SAME

(71) Applicant: Samsung Electronics Co., Ltd., Suwon-si (KR)

(72) Inventors: Yejeong Seo, Suwon-si (KR); Hyuk Kim, Suwon-si (KR)

(21) Appl. No.: 18/964,108

(22) Filed: Nov. 29, 2024

(30) Foreign Application Priority Data
Jan. 25, 2024 (KR) 10-2024-0011555

(51) Int. Cl. H10B 43/35; H10B 43/40; H10B 43/50

(52) U.S. Cl. CPC H10B 43/35; H10B 43/40; H10B 43/50

(57) ABSTRACT

A semiconductor device includes a stack structure comprising lower and upper stack regions, a vertical channel structure penetrating the stack structure, and lower gate contact structures contacting lower gate contact regions of lower gate layers of the lower stack region and penetrating the upper stack region. A first lower gate contact structure of the lower gate contact structures comprises a first upper contact portion penetrating the upper stack region, and a first lower contact portion extending downwardly from the first upper contact portion, a side surface of the first lower gate contact structure comprises a first contact bending portion extending to a side surface of the first lower contact portion, a side surface of the vertical channel structure comprises a channel bending portion, and at least a portion of the channel bending portion is disposed at the same level as at least a portion of the first contact bending portion.

### CROSS-REFERENCE TO RELATED APPLICATION(S)

This application claims benefit of priority to Korean Patent Application No. 10-2024-0011555 filed on Jan. 25, 2024 in the Korean Intellectual Property Office, the disclosure of which is herein incorporated by reference in its entirety.

### BACKGROUND

The present inventive concept relates to a semiconductor device and a data storage system including the same.

In electronic systems having data storage, semiconductor devices capable of storing high-capacity data are desirable. Accordingly, methods of increasing a data storage capacity of semiconductor devices are being researched. For example, as one method of increasing a data storage capacity of a semiconductor device, a semiconductor device including memory cells which are three-dimensionally arranged, instead of memory cells which are two-dimensionally arranged, has been proposed.

### SUMMARY

An aspect of the present inventive concept is to provide a semiconductor device having increased integration.

An aspect of the present inventive concept is to provide a data storage system including the semiconductor device.

According to an aspect of the present disclosure, a semiconductor device, includes: a stack structure comprising a lower stack region and an upper stack region on the lower stack region, wherein the lower stack region comprises lower gate layers and lower interlayer insulating layers alternately stacked in a vertical direction, and the upper stack region comprises upper gate layers and upper interlayer insulating layers alternately stacked in the vertical direction; a vertical channel structure penetrating the stack structure in the vertical direction and comprising a data storage structure and a channel layer; lower gate contact structures contacting lower gate contact regions of the lower gate layers, extending upwardly, and penetrating the upper stack region; and upper gate contact structures contacting upper gate contact regions of the upper gate layers, and extending upwardly, wherein each of the lower and upper gate contact structures comprises a conductive contact plug and an insulating spacer on a side surface of the conductive contact plug, a first lower gate contact structure of the lower gate contact structures comprises a first upper contact portion penetrating the upper stack region, and a first lower contact portion extending downwardly from the first upper contact portion and contacting a first lower gate layer of the lower gate layers, a side surface of the first lower gate contact structure comprises a first contact bending portion, bent from a side surface of the first upper contact portion and extending to a side surface of the first lower contact portion, the vertical channel structure comprises an upper channel portion penetrating the upper stack region, and a lower channel portion extending from the upper channel portion and penetrating the lower stack region, a side surface of the vertical channel structure comprises a channel bending portion, bent from a side surface of the upper channel portion and extending to a side surface of the lower channel portion, and at least a portion of the channel bending portion is disposed at the same level as at least a portion of the first contact bending portion.

According to an aspect of the present disclosure, a semiconductor device includes: a stack structure comprising a lower stack region and an upper stack region on the lower stack region, wherein the lower stack region comprises lower gate layers and lower interlayer insulating layers stacked in a vertical direction, and the upper stack region comprises upper gate layers and upper interlayer insulating layers stacked in the vertical direction; a separation structure penetrating the stack structure in the vertical direction and extending in a first horizontal direction; a vertical channel structure penetrating the stack structure in the vertical direction and comprising a data storage structure and a channel layer; lower gate contact structures contacting lower gate contact regions of the lower gate layers, extending upwardly, and penetrating the upper stack region; and upper gate contact structures contacting upper gate contact regions of the upper gate layers, and extending upwardly, wherein each of the lower and upper gate contact structures comprises a conductive contact plug and an insulating spacer on a side surface of the conductive contact plug, the conductive contact plugs of the lower gate contact structures contact the lower gate contact regions, the conductive contact plugs of the upper gate contact structures contact the upper gate contact regions, a first lower gate contact structure of the lower gate contact structures comprises a first upper contact portion penetrating the upper stack region, and a first lower contact portion extending downwardly from the first upper contact portion and contacting a first lower gate layer of the lower gate layers, a side surface of the first lower gate contact structure comprises a first contact bending portion, bent from a side surface of the first upper contact portion and extending to a side surface of the first lower contact portion, the separation structure comprises an upper separation portion penetrating the upper stack region and a lower separation portion extending from the upper separation portion and penetrating the lower stack region, a side surface of the separation structure comprises a separation bending portion, bent from a side surface of the upper separation portion and extending to a side surface of the lower separation portion, and at least a portion of the separation bending portion is disposed at substantially the same level as at least a portion of the first contact bending portion.

According to an aspect of the present inventive concept, a data storage system includes: a semiconductor device comprising an input/output pad; and a controller electrically connected to the semiconductor device via the input/output pad and controlling the semiconductor device, wherein the semiconductor device, comprising: a stack structure comprising a lower stack region and an upper stack region on the lower stack region, wherein the lower stack region comprises lower gate layers and lower interlayer insulating layers alternately stacked in a vertical direction, and the upper stack region comprises upper gate layers and upper interlayer insulating layers alternately stacked in the vertical direction; a separation structure penetrating the stack structure in the vertical direction and extending in a first horizontal direction; a vertical channel structure penetrating the stack structure in the vertical direction and comprising a data storage structure and a channel layer; lower gate contact structures contacting lower gate contact regions of the lower gate layers, extending upwardly, and penetrating the upper stack region; and upper gate contact structures contacting upper gate contact regions of the upper gate layers, and extending upwardly, each of the lower and upper gate contact structures comprises a conductive contact plug and an insulating spacer on a side surface of the conductive contact plug, a first lower gate contact structure of the lower gate contact structures comprises a first upper contact portion penetrating the upper stack region, and a first lower contact portion extending downwardly from the first upper contact portion and contacting a first lower gate layer of the lower gate layers, a side surface of the first lower gate contact structure comprises a first contact bending portion, bent from a side surface of the first upper contact portion and extending to a side surface of the first lower contact portion, the vertical channel structure comprises an upper channel portion penetrating the upper stack region, and a lower channel portion extending from the upper channel portion and penetrating the lower stack region, a side surface of the vertical channel structure comprises a channel bending portion, bent from a side surface of the upper channel portion and extending to a side surface of the lower channel portion, and at least a portion of the channel bending portion is disposed at the same level as at least a portion of the first contact bending portion.

### BRIEF DESCRIPTION OF DRAWINGS

The above and other aspects, features, and advantages of the present inventive concept will be more clearly understood from the following detailed description, taken in conjunction with the accompanying drawings, in which:

FIGS. 1, 2, 3A, 3B, 3C, 3D, 4A, 4B, 4C, 4D, 5 and 6 are diagrams illustrating a semiconductor device according to an embodiment of the present inventive concept;

FIG. 7 is a cross-sectional view illustrating a semiconductor device according to an embodiment of the present inventive concept;

FIGS. 8, 9, 10A to 10D, 11, and 12 are diagrams illustrating a semiconductor device according to an embodiment of the present inventive concept;

FIGS. 13 and 14 are cross-sectional views illustrating a semiconductor device according to an embodiment of the present inventive concept;

FIGS. 15 and 16 are cross-sectional views illustrating a semiconductor device according to an embodiment of the present inventive concept;

FIGS. 17, 18, 19A, 19B, 20A, 20B, 21A, 21B, 22A, 22B, 23A and 23B are diagrams illustrating an example of a semiconductor device manufacturing method according to an embodiment of the present inventive concept;

FIG. 24 is a diagram illustrating a data storage system including a semiconductor device according to an exemplary embodiment of the present inventive concept; and

FIG. 25 is a perspective view illustrating a data storage system including a semiconductor device according to an embodiment of the present inventive concept.

### DETAILED DESCRIPTION

Hereinafter, example embodiments of the present inventive concept will be described with reference to the accompanying drawings. Hereinafter, terms such as “upper,” “middle,” and “lower” may be replaced with other terms, for example, “first,” “second,” and “third” to describe elements of the specification. Terms such as “first,” “second,” and “third” may be used to describe different elements, but the elements are not limited by the terms, and a “first element” may be referred to as a “second element.”

In the specification, a “bending portion” of a side surface of an element may mean a portion bent from an upper side surface immediately above the bending portion and a lower side surface immediately below the bending portion, and the “bending portion” may also be referred to by the term “bent portion.” For example, the “bending portion” of an element may refer to a portion that is bent from an upper side surface directly above the bending portion toward a lower side surface directly below the bending portion, thereby connecting the upper side surface to the lower side surface. The lower side surface may be closer to the inside of the element than the upper side surface. A portion of the element having the bending portion may have a decreasing width from a first width of an upper portion having the upper side surface to a second width of a lower portion having the lower side surface. In an embodiment, a “bending portion” of a side surface may refer to a “junction portion” of the side surface formed by an upper side surface immediately above the bending portion and a lower side surface immediately below the bending portion being misaligned vertically.

In the specification, a height relationship between bending portions and height levels of the bending portions may be clearly understood from the drawings attached hereto.

In the specification, bending portions referred to by the same symbol may be disposed at the same level.

In the specification, bending portions of a side surface of a component may be spaced apart from each other in a vertical direction. For example, when a side surface of a gate contact structure has a plurality of contact bending portions, the plurality of contact bending portions may be spaced apart from each other in the vertical direction.

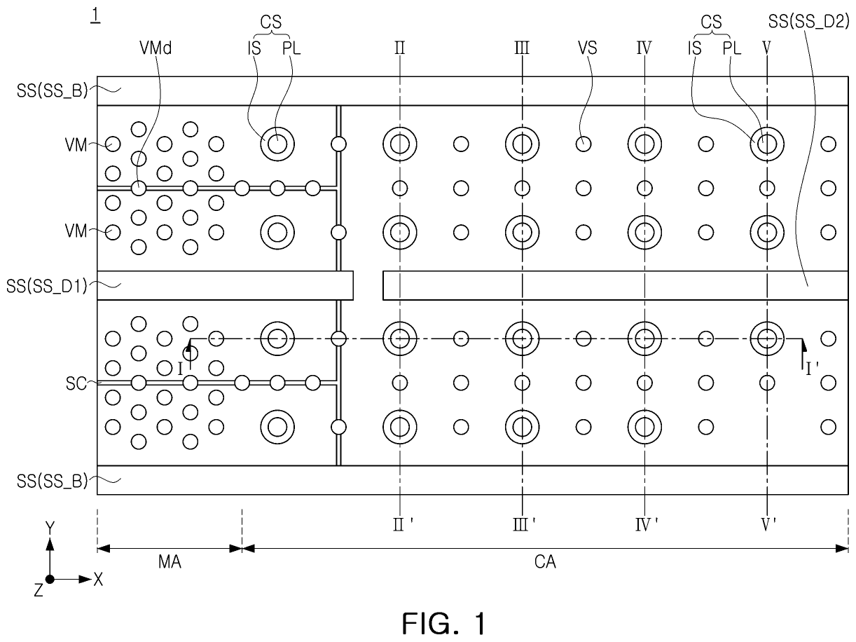

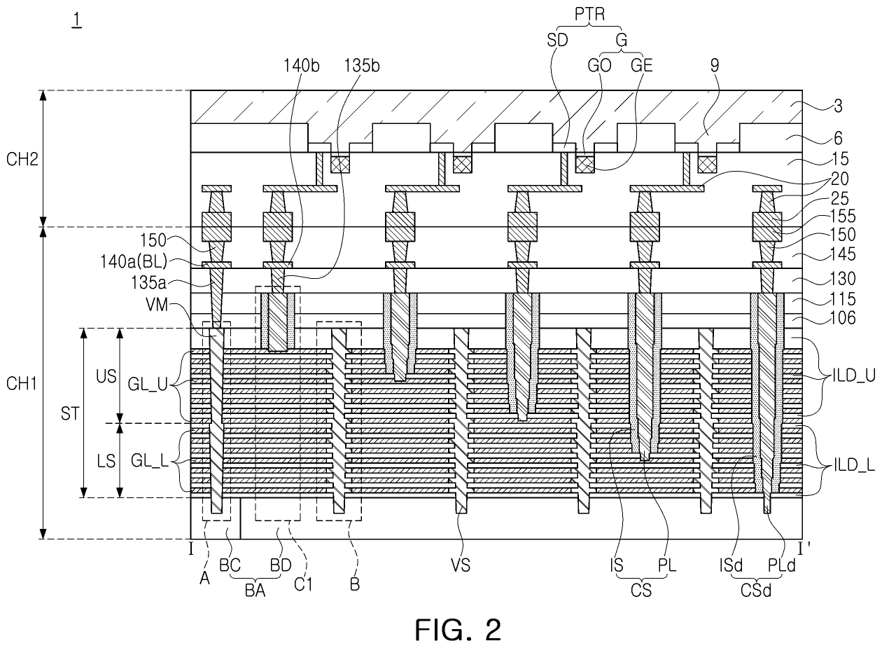

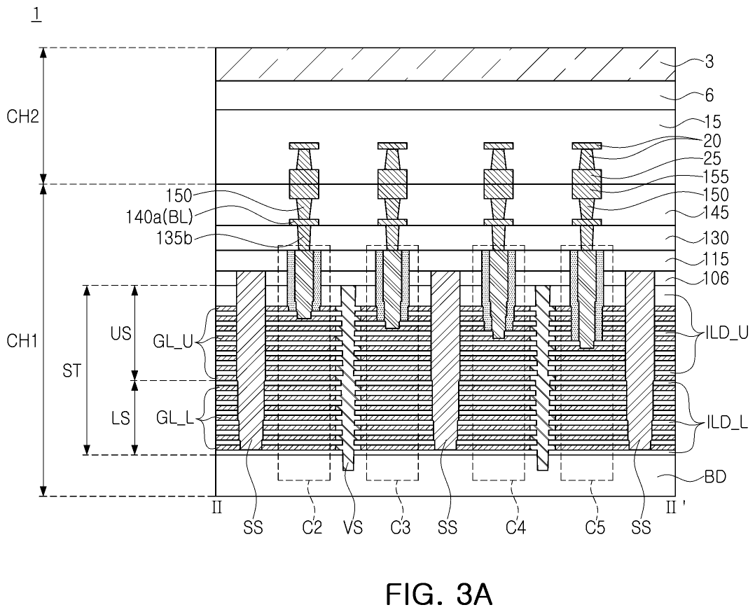

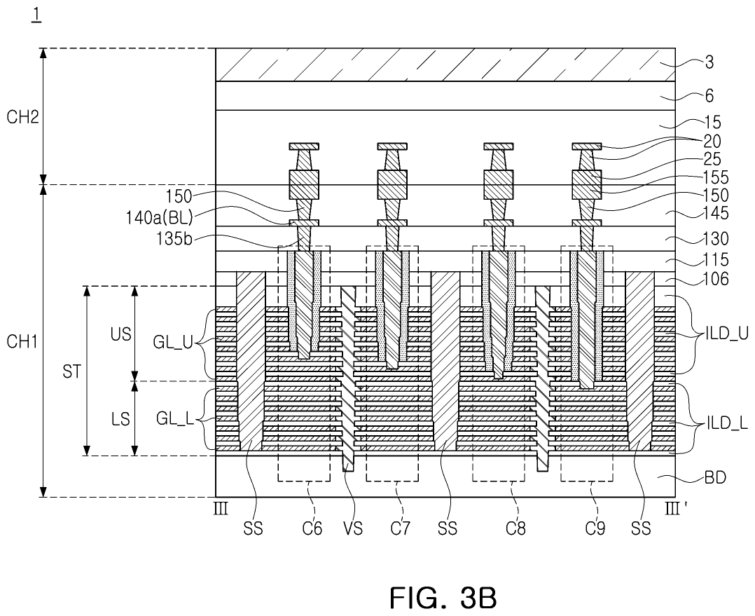

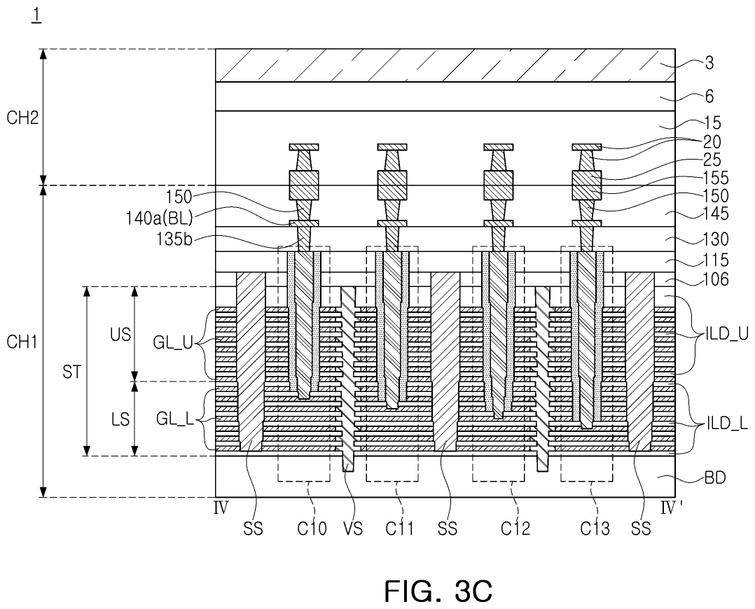

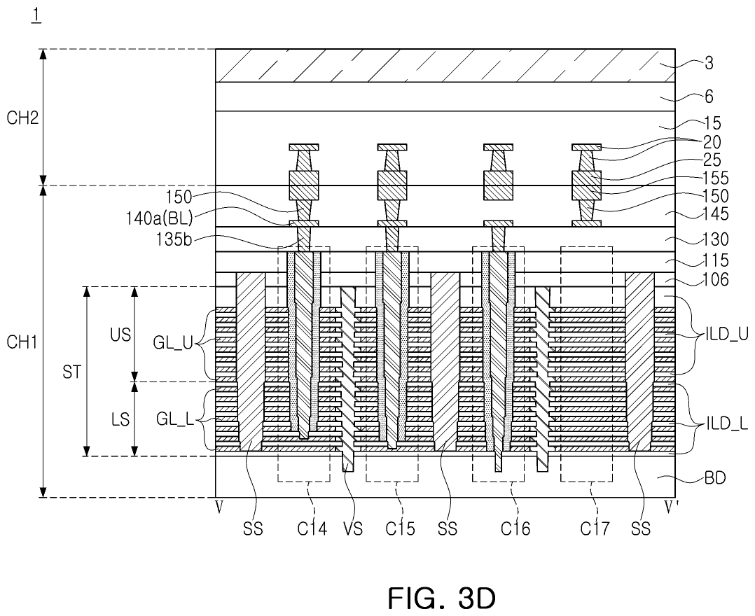

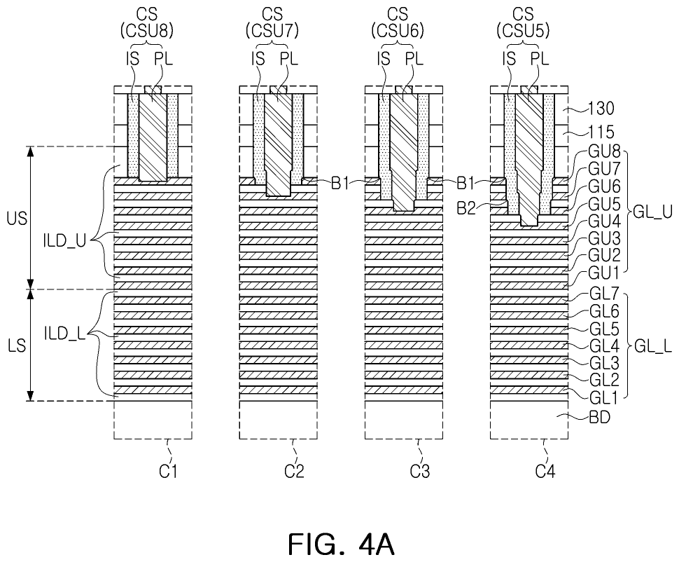

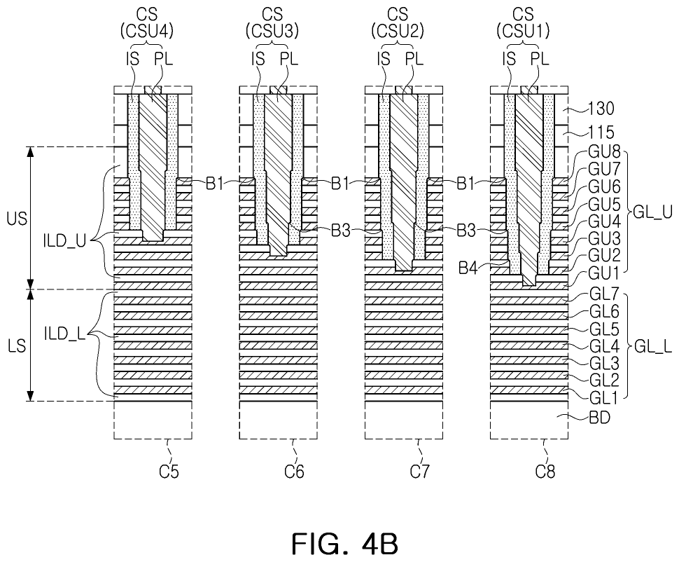

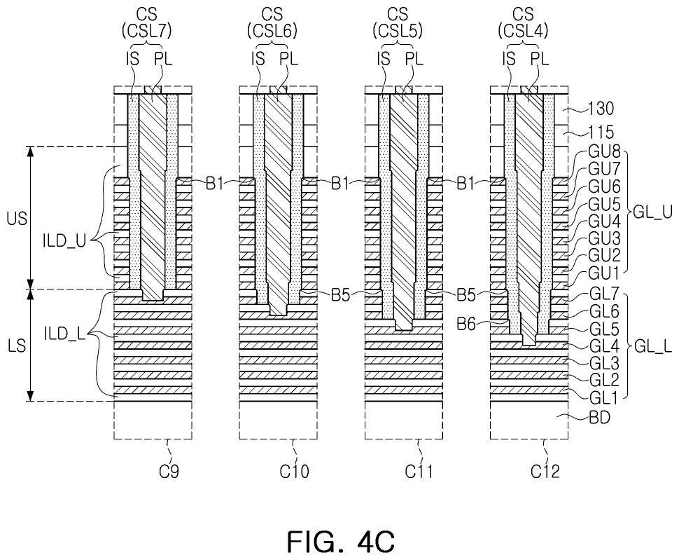

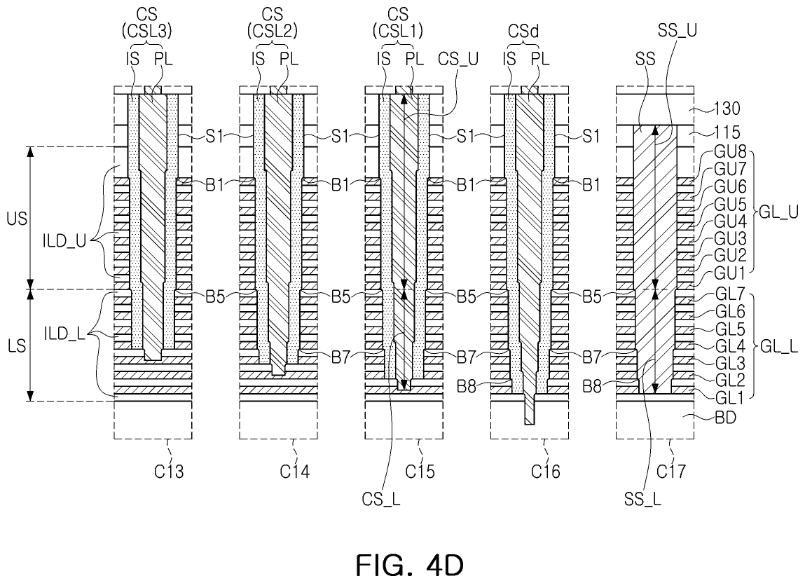

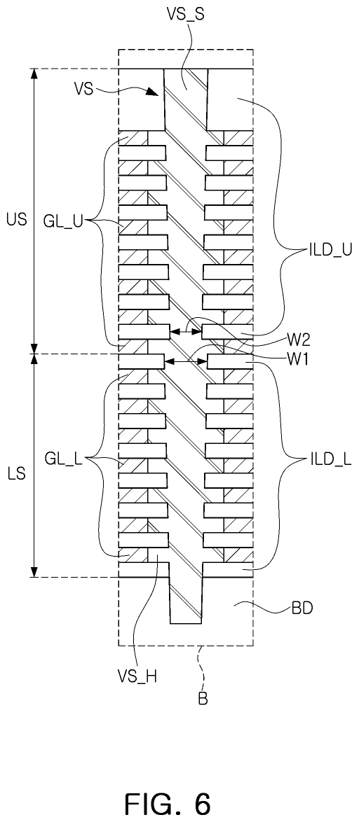

First, with reference to FIGS. 1 to 6, a semiconductor device according to an embodiment of the present inventive concept will be described. FIGS. 1, 2, 3A, 3B, 3C, 3D, 4A, 4B, 4C, 4D, 5 and 6 are diagrams illustrating a semiconductor device according to an embodiment of the present inventive concept: FIG. 1 is a top view illustrating a semiconductor device according to an embodiment of the present inventive concept; FIG. 2 is a cross-sectional view illustrating a region taken along line I-I′ in FIG. 1; FIG. 3A is a cross-sectional view illustrating a region taken along line II-II′ in FIG. 1; FIG. 3B is a cross-sectional view illustrating a region taken along line III-III′ in FIG. 1; FIG. 3C is a cross-sectional view illustrating a region taken along line IV-IV′ in FIG. 1; FIG. 3D is a cross-sectional view illustrating a region taken along line V-V′ in FIG. 1; FIG. 4A is partially enlarged views illustrating regions marked C1 in FIGS. 2 and C2, C3 and C4 in FIG. 3A; FIG. 4B is partially enlarged views illustrating regions marked C5 in FIG. 3A and C6, C7 and C8 in FIG. 3B; FIG. 4C is partially enlarged views illustrating regions marked C9 in FIG. 3B and C10, C11 and C12 in FIG. 3C; and FIG. 4D is partially enlarged views illustrating regions marked C13 in FIG. 3C and C14, C15, C16 and C17 in FIG. 3D.

Referring to FIGS. 1 to 6, a semiconductor device 1 according to an embodiment may include a first chip structure CH1 and a second chip structure CH2 vertically overlapping the first chip structure CH1. The second chip structure CH2 may be disposed on the first chip structure CH1.

The first chip structure CH1 may include a memory cell array area MA and a connection area CA adjacent to the memory cell array area MA.

The first chip structure CH1 may be referred to as a memory structure, and the second chip structure CH2 may be referred to as a peripheral circuit structure.

The first chip structure CH1 may include a base BA and a stack structure ST on the base BA. The base BA may include a base conductive pattern BC and a base insulating pattern BD on a side surface of the base conductive pattern BC.

The base conductive pattern BC may include or may be formed of at least one of a conductive material such as doped silicon and a conductive material such as metal and metal nitride. For example, the base conductive pattern BC may include or may be formed of a silicon layer having N-type conductivity, which may be configured as a common source.

The stack structure ST may include a lower stack region (LS) and an upper stack region US on the lower stack region LS.

The lower stack region LS may include lower gate layers GL_L and lower interlayer insulating layers ILD_L alternately stacked in a vertical direction Z. The upper stack region US may include upper gate layers GL_U and upper interlayer insulating layers ILD_U stacked in the vertical direction Z.

The lower and upper interlayer insulating layers ILD_L and ILD_U may include or may be formed of an insulating material such as silicon oxide.

The lower and upper gate layers GL_L and GL_U may be gate electrodes. The lower and upper gate layers GL_L and GL_U may be conductive layers. Each of the lower and upper gate layers GL_L and GL_U may be made of W, Ru, Mo, Nb, Ni, Co, Ti, Ta, TiN, TaN, WN, NbN, TiAl, TiAlN, TiSi, TiSiN, TaSi, TaSiN, RuTiN, NiSi, CoSi or a combination thereof, but the present inventive concept is not limited thereto. For example, each of the lower and upper gate layers GL_L and GL_U may be a single layer or multiple layers of the materials described above.

The lower gate layers GL_L may include a lower selection gate electrode and a plurality of lower word lines disposed on the lower selection gate electrode. The upper gate layers GL_U may include a plurality of upper word lines and an upper selection gate electrode disposed on the plurality of upper word lines. Here, the upper selection gate electrode may be configured as a string selection gate electrode or a string selection gate line.

The first chip structure CH1 may include a first capping insulating layer 106, a second capping insulating layer 115, a third capping insulating layer 130 and a fourth capping insulating layer 145, sequentially stacked on the stack structure ST. In an embodiment, the first to fourth capping insulating layers 106, 115, 130, and 145 may include or may be formed of an insulating material such as silicon oxide and silicon nitride.

The first chip structure CH1 may further include separation structures SS penetrating the stack structure ST in the vertical direction Z. Each of the separation structures SS may have a line shape extending in a first horizontal direction X. The separation structures SS may include block separation structures SS_B crossing the memory cell array area MA and the connection area CA, and dummy separation structures SS_D1 and SS_D2 disposed between the block separation structures SS_B. The dummy separation structures SS_D1 and SS_D2 may include a first dummy separation structure SS_D1 crossing the memory cell array area MA and extending into the connection area CA, and a second dummy separation structure SS_D1 disposed in the connection area CA. In an example, the separation structures SS may be formed of an insulating material. For example, each of the separation structures SS may include at least one of silicon oxide or silicon nitride. In an embodiment, each of the separation structures SS may be formed of a conductive pattern and an insulating spacer covering a side surface of the conductive pattern. For example, the conductive pattern of each of the separation structures SS may include at least one of polysilicon, W, or TiN, and the insulating spacer of each of the separation structures SS may include at least one of silicon oxide or silicon nitride.

The first chip structure CH1 may further include a string separation region SC separating an upper gate layer that may be a string selection gate electrode among the upper gate layers GL_U. For example, when an uppermost gate layer of the upper gate layers GL_U is a string selection gate electrode, the string separation region SC may penetrate the uppermost gate layer and separate the uppermost gate layer into string selection gate electrodes spaced apart from each other in a horizontal direction. The string separation region SC may be formed of an insulating material. When viewed in a plan view, the string separation region SC may extend in the first horizontal direction X, and the string selection gate electrodes separated by the string separation region SC may be spaced apart from each other in a second horizontal direction Y perpendicular to the first horizontal direction X.

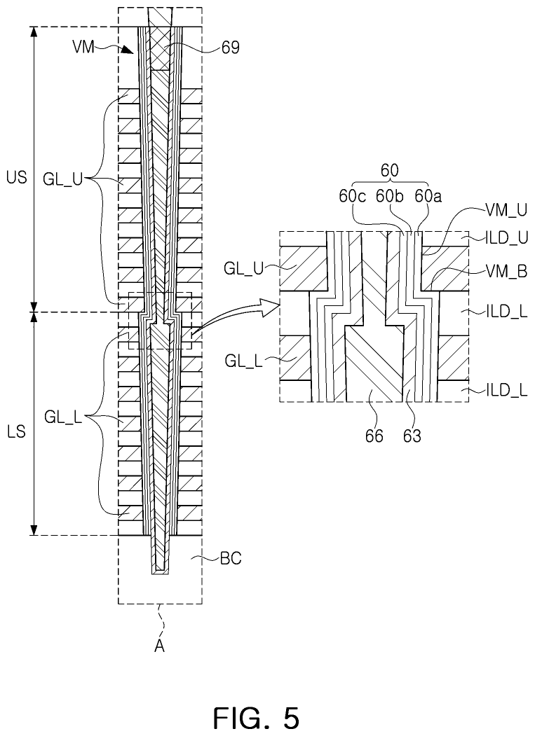

The first chip structure CHI may further include a vertical channel structure VM penetrating the stack structure ST in the vertical direction Z and including a data storage structure (60 in FIG. 5) and a channel layer (63 in FIG. 5).

The vertical channel structure VM may be disposed within the memory cell array area MA.

The vertical channel structure (VM in FIG. 5) may further include an insulating core region 66 and a pad pattern 69. The channel layer 63 may be disposed on a side surface of the insulating core region 66 and connected to the base conductive pattern BC. The data storage structure 60 may be disposed on an outer surface of the channel layer 63. The pad pattern 69 may be disposed on the insulating core region 66 and connected to the channel layer 63.

The insulating core region 66 may include an insulating material such as silicon oxide. The channel layer 63 may cover a side surface and a lower surface of the insulating core region 66. The channel layer 63 may include a semiconductor material such as polysilicon, single crystal silicon and oxide semiconductor. A portion of the base conductive pattern BC in contact with the channel layer 63 may include at least doped silicon. For example, the base conductive pattern BC may include polysilicon having N-type conductivity. Depending on the embodiment, the base conductive pattern BC may include polysilicon having N-type conductivity and polysilicon having P-type conductivity.

The data storage structure 60 may include a first dielectric layer 60a, a second dielectric layer 60c and a data storage layer 60b between the first and second dielectric layers 60a and 60c. The second dielectric layer 60c may contact the channel layer 63.

The first dielectric layer 60a may be configured as a blocking dielectric layer. The first dielectric layer 60a may include or may be formed of at least one of silicon oxide and a high dielectric material. The second dielectric layer 60c may be configured as a tunneling dielectric layer. The second dielectric layer 60c may include silicon oxide or silicon oxide doped with impurities.

The data storage layer 60b may include an insulating material such as silicon nitride capable of storing information by trapping a charge. The data storage layer 60b may include areas capable of storing information in a semiconductor device such as a flash memory device.

In the present embodiment, the data storage structure 60 includes the data storage layer 60b capable of storing information by trapping a charge, but the present inventive concept is not limited thereto. For example, the data storage structure 60 may be a data storage structure used in a ferroelectric memory that can store information using remnant polarization caused by a dipole.

The pad pattern 69 may include or may be formed of doped polysilicon.

The vertical channel structure VM may include an upper channel portion penetrating the upper stack region US and a lower channel portion extending from the upper channel portion and penetrating the lower stack region LS.

The side surface of the vertical channel structure VM may include a channel bending portion VM_B, bent from a side surface (VM_U in FIG. 5) of the upper channel portion and extending to a side surface (VM_L in FIG. 5) of the lower channel portion.

The channel bending portion VM_B may be disposed at a level higher than that of a lower surface of an uppermost gate layer of the lower gate layers GL_L and lower than that of an upper surface of a lowermost gate layer of the upper gate layers GL_U. The channel bending portion VM_B may be disposed below a lower surface of the lowermost upper gate layer of the upper gate layers GL_U.

The first chip structure CH1 may further include gate contact structures CS connected to the lower and upper gate layers GL_L and GL_U, respectively. The first chip structure CH1 may further include an additional contact structure CSd penetrating the stack structure ST.

Each of the gate contact structures CS and the additional contact structure CSd may include a conductive contact plug PL and an insulating spacer IS on a side surface of the conductive contact plug PL. In each of the gate contact structures CS, the conductive contact plug PL may be in contact with and connected to a gate contact region of any one gate layer, and the insulating spacer IS may electrically insulate the conductive contact plug PL from the gate layers adjacent to the side surface of the conductive contact plug PL. The conductive contact plug PL may continuously extend from a lower surface in contact with a gate contact region of the gate layer to an upper surface.

In an embodiment, the upper gate layers GL_U may include first to eighth upper gate layers GU1 to GU8 sequentially stacked, and the lower gate layers GL_L may include first to seventh lower gate layers GL1 to GL7 sequentially stacked.

The numbers of the lower and upper gate layers GL_L and GL_U are exemplary, and the present inventive concept is not limited to the numbers thereof illustrated in the drawings.

The gate contact structures CS may include first to seventh lower gate contact structures CSL1 to CSL7 contacting the first to seventh lower gate layers GL1 to GL7 and first to eighth upper gate contact structures CSU1 to CSU8 contacting upper gate contact regions of the first to eighth upper gate layers GU1 to GU8 and extend vertically. The first to seventh lower gate contact structures CSL1 to CSL7 may extend vertically and extend into the lower stack region LS through the upper stack region US, thereby lower ends of the first to seventh lower gate contact structures CSL1 to CSL7 being positioned in the lower stack region LS. The first to eighth upper gate contact structures CSU1 to CSU8 may partially penetrate the upper stack region US, thereby lower ends of the first to eighth gate contact structures CSU1 to CSU8 being positioned in the upper stack region US.

In the eighth upper gate contact structure CSU8, the insulating spacer IS and the conductive contact plug PL may contact the eighth upper gate layer GU8. For example, the insulating spacer IS may contact an upper surface of the eight upper gate layer GU8, and a lower end of the conductive contact plug PL may be buried in the eight upper gate layer GU8.

In the seventh upper gate contact structure CSU7, the insulating spacer IS may be disposed at a level higher than that of the seventh upper gate layer GU7, and the contact plug PL may contact the seventh upper gate layer GU7. Accordingly, in the seventh upper gate contact structure CSU7, a lower end of the insulating spacer IS may be disposed at a level higher than that of a lower end of the contact plug PL. In the seventh upper gate contact structure CSU7, the lower end of the contact plug PL may be buried in the seventh upper gate layer GU7. Similarly, in the first to sixth upper gate contact structures CSU1 to CSU6, the conductive contact plugs PL may contact the first to sixth upper gate layers GU1 to GU6, respectively.

Side surfaces of the first to seventh upper gate contact structures CSU1 to CSU7 and the first to seventh lower gate contact structures CSL1 to CSL7 may include a contact bending portion B1 at a level higher than that of a lower surface of the uppermost eighth upper gate layer GU8.

The fifth upper contact structure (CSU5 in FIG. 4A) may further include a contact bending portion B2.

The contact bending portion B2 may be disposed at a level higher than that of an upper surface of the sixth upper gate layer GU6, and may be disposed at a level lower than that of an upper surface of the seventh upper gate layer GU7.

Side surfaces of the first to fourth upper contact structures (CSU1 to CSU4 in FIG. 4B) may not include a bending portion at the same level as the contact bent portion B2.

Hereinafter, “a side surface does not include a bending portion” may mean that there is no bending portion of the same shape as the bending portion.

The first to third upper contact structures (CSU1 to CSU3 in FIG. 4B) may further include a contact bending portion B3.

The contact bending portion B3 may be disposed at a level higher than that of an upper surface of the fourth upper gate layer GU4 and may be disposed at a level lower than that of an upper surface of the fifth upper gate layer GU5.

The first upper contact structure (CSU1 in FIG. 4B) may further include a contact bending portion B4.

The contact bending portion B4 may be disposed at a level higher than that of an upper surface of the second upper gate layer GU2 and may be disposed at a level lower than that of an upper surface of the third upper gate layer GU3.

Side surfaces of the first to seventh lower gate contact structures CSL1 to CSL7 may not include a contact bending portion at the same levels as the contact bending portion B2, the contact bending portion B3 and the contact bending portion B4.

Side surfaces of the first to sixth lower gate contact structures CSL1 to CSL6 may further include a contact bending portion B5 disposed at the same level as the channel bending portion (VM_B in FIG. 5). For example, the contact bending portion B5 may be located at the interface between the upper stack region US and the lower stack region LS. The interface may be located at a lower surface of a lowermost upper gate layer GU1. The channel bending portion VM_B in FIG. 5 may be located at the interface between the upper stack region US and the lower stack region LS (i.e., located at the lower surface of the lowermost upper gate layer GU1).

A side surface of the fourth lower gate contact structure CSL4 may further include a contact bending portion B6. The contact bending portion B6 may be disposed at a level higher than that of an upper surface of the fifth lower gate layer GL5 and may be disposed at a level lower than that of an upper surface of the sixth lower gate layer GL6.

Side surfaces of the first and second lower gate contact structures CSL1 and CSL2 may further include a contact bending portion B7. The contact bending portion B7 may be disposed at a level higher than that of an upper surface of the third lower gate layer GL3 and may be disposed at a level lower than that of an upper surface of the fourth lower gate layer GL4.

The first lower gate contact structure CSL1 may comprise a first upper contact portion CS_U penetrating the upper stack region US, and a first lower contact portion CS_L extending downwardly from the first upper contact portion CS_U and contacting the first lower gate layer GL1 of the lower gate layers. A side surface of the first lower gate contact structure CSL1 may include the contact bending portion B5, bent from a side surface of the first upper contact portion and extending to a side surface of the first lower contact portion CS_L. The contact bending portion B5 may be located at an interface between the upper stack region US and the lower stack region LS. The first lower gate contact structure CSL1 may be divided into the first upper contact portion CS_U and the first lower contact portion CS_L by the contact bending portion B5.

Bending portions of side surfaces of the gate contact structures CS may correspond to bending portions of side surfaces of the insulating spacers IS. Similarly, a side surface of the conductive contact plug PL may include bending portions that have substantially the same shape as the bending portions on the side surface of the insulating spacer IS. Additionally, the side surface of the conductive contact plug PL may further include a lower bending portion adjacent to a lower end of the insulating spacer IS, compared to the side surface of the insulating spacer IS.

At least a portion of the channel bending portion VM_B may be disposed at substantially the same level as at least a portion of the contact bending portion B5.

The additional contact structure CSd may include the contact bending portions B1, B5 and B7.

The additional contact structure CSd may further include a contact bending portion B8. The contact bending portion B8 may be disposed at a level higher than that of an upper surface of the first lower gate layer GL1 and may be disposed at a level lower than that of an upper surface of the second lower gate layer GL2.

A conductive contact plug PLd of the additional contact structure CSd may contact the base insulating pattern BD, and an insulating spacer ISd of the additional contact structure CSd may surround a side surface of the conductive contact plug PLd, and may be disposed at a level higher than that of the base insulating pattern BD.

Side surfaces of the separation structures SS may include bending portions B5, B7 and B8 corresponding to the contact bending portions B5, B7 and B8, respectively. For example, the bending portions B5, B7, and B8 of the separation structures SS may be positioned at the same level of the contact bending portions B5, B7, and B8, respectively. The separation structures SS may include an upper separation part SS_U penetrating the upper stack region US and a lower separation part SS_L extending downwardly from the upper separation part SS_U.

A side surface of the separation structure SS may include the separation bending portion B5, bent from a side surface of the upper separation portion SS_U and extending to a side surface of the lower separation portion SS_L, and at least a portion of the separation bending portion B5 may be disposed at substantially the same level as at least a portion of the contact bending portion B5. The contact bending portion B5 may be located at an interface between the upper stack region US and the lower stack region LS. The separation structure SS may be divided into the first upper separation portion SS_U and the first lower separation portion SS_L by the separation bending portion B5.

A width of the lower separation portion SS_L penetrating an uppermost lower gate layer GL7 of the lower gate layers GL_L may be different from a width of the upper separation portion SS_U penetrating a lowermost upper gate layer GU1 of the upper gate layers GL_U. For example, the width (i.e., a second width) of the lower separation portion SS_L penetrating the uppermost lower gate layer GL7 of the lower gate layers GL_L may be less than the width (i.e., a first width) of the upper separation portion SS_U penetrating the lowermost upper gate layer GUI of the upper gate layers GL_U. The separation bending portion B5 may have a decreasing width from the first width to the second width.

The upper gate layers GL_U may surround the side surfaces of the first to seventh lower gate contact structures CSL1 to CSL7 and may be spaced apart from the conductive contact plugs PL of the first to seventh lower gate contact structures CSL1 to CSL7 by the insulating spacers IS.

Among the lower gate layers GL_L, a lower gate layer disposed at a level higher than that of the first lower gate layer GL1 may surround a side surface of the first lower gate contact structure CSL1.

The conductive contact plug PL of the first lower gate contact structure CSL1 may contact the first lower gate layer GL1, and the insulating spacer IS of the first lower gate contact structure CSL1 may be disposed at a level higher than that of the first lower gate layer GL1 and spaced apart from the first lower gate layer GL1. For example, in the first lower gate contact structure CSL1, a lower end of the conductive contact plug PL may be buried in the first lower gate layer GL1, and a lower end of the insulating spacer IS may be positioned higher than the lower end of the conductive contact plug PL.

The first chip structure CH1 may further include vertical support structures VS disposed in the connection area CA. Each of the vertical support structures VS may include a vertical pillar VS_V and protrusions VS_H extending in a horizontal direction from a side surface of the vertical pillar VS_V toward the gate layers GL_L and GL_U. The vertical support structures VS may be formed of an insulating material. For example, the vertical support structures VS may not include a material of the channel layer 63 of the vertical channel structure VM. For example, a material of the vertical support structures VS may be different from a material of the channel layer 63. The material of the vertical support structures VS may include silicon oxide, and the material of the channel layer 63 may include polysilicon or oxide semiconductor. The vertical support structures VS may prevent deformation of the lower and upper gate layers GL_L and GL_U.

The gate contact structures CS may have an upper surface coplanar with an upper surface of the second capping insulating layer 115. The separation structures SS may have an upper surface coplanar with an upper surface of the first capping insulating layer 106.

The first chip structure CH1 may further include a contact plug 135a on the vertical channel structure VM and a bit line 140a (BL) on the contact plug 135a.

The first chip structure CH1 may further include contact plugs 135b on the gate contact structures CS and a gate interconnection structure 140b on the contact plugs 135b.

The first chip structure CH1 may further include first bonding pads 155 coplanar with an upper surface of the fourth capping insulating layer 145 and an interconnection structure 150 below the first bonding pads 155.

The second chip structure CH2 may include a substrate 3, peripheral active regions 9 below the substrate 3, and a peripheral element separation region 6 defining the peripheral active regions 9 below the substrate 3. The substrate 3 may be configured as a semiconductor substrate.

The second chip structure CH2 may further include peripheral elements PTR below the substrate 3, routing interconnection structures 20 and 25, and an insulating structure 15.

The peripheral elements PTR may form a peripheral circuit. The peripheral elements PTR may include peripheral source/drain regions SD spaced apart from each other within the peripheral active region 9, and a peripheral transistor including a peripheral gate PG below the peripheral active region between the peripheral source/drain regions SD. The peripheral gate PG may include a peripheral gate dielectric GO and a peripheral gate electrode GE. The routing interconnection structures 20 and 25 may be embedded in the insulating structure 15 and electrically connected to the peripheral elements PTR. The routing interconnection structures 20 and 25 may include interconnection portions 20 including horizontal portions and vertical portions, and second bonding pads 25 having a lower surface coplanar with a lower surface of the insulating structure 15 below the interconnection portions 20. The first bonding pads 155 and the second bonding pads 25 may be bonded with each other through an inter-metal bonding process.

Hereinafter, various modifications to the above-described embodiment will be described to increase the degree of integration and improve reliability of the semiconductor device 1. The various modifications of the components of the above-described embodiments described below will be described focusing on modified components, replaced components or added components. In addition, the components that can be modified or replaced below are described with reference to the drawings below, but the components that can be modified or replaced may be combined with each other or with the components described above to configure a semiconductor device according to an embodiment of the present inventive concept.

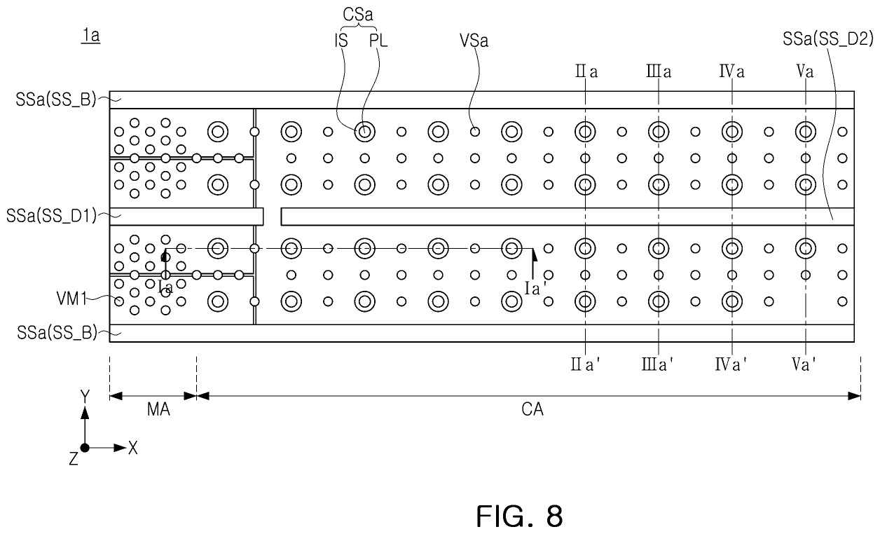

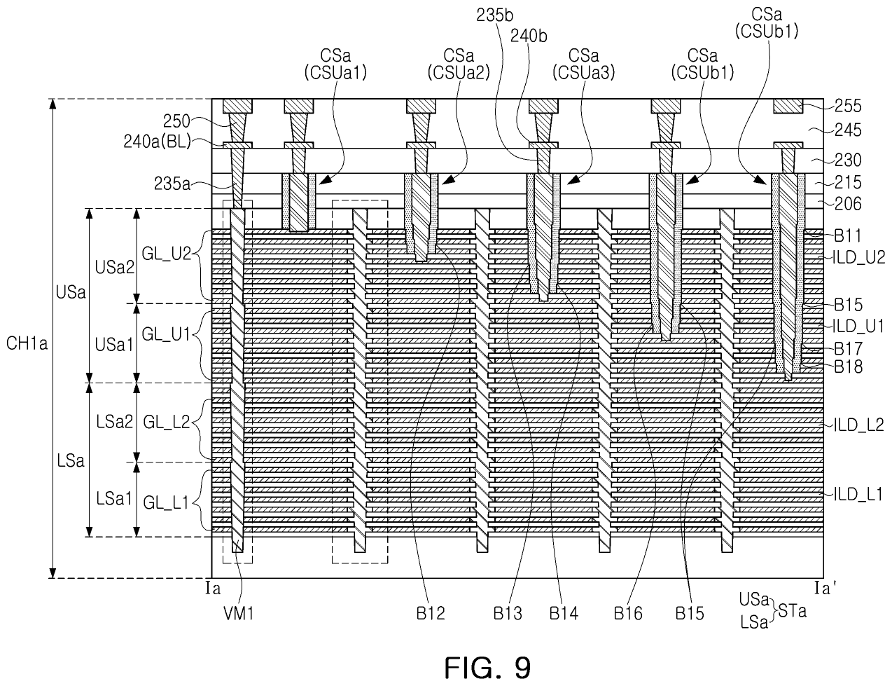

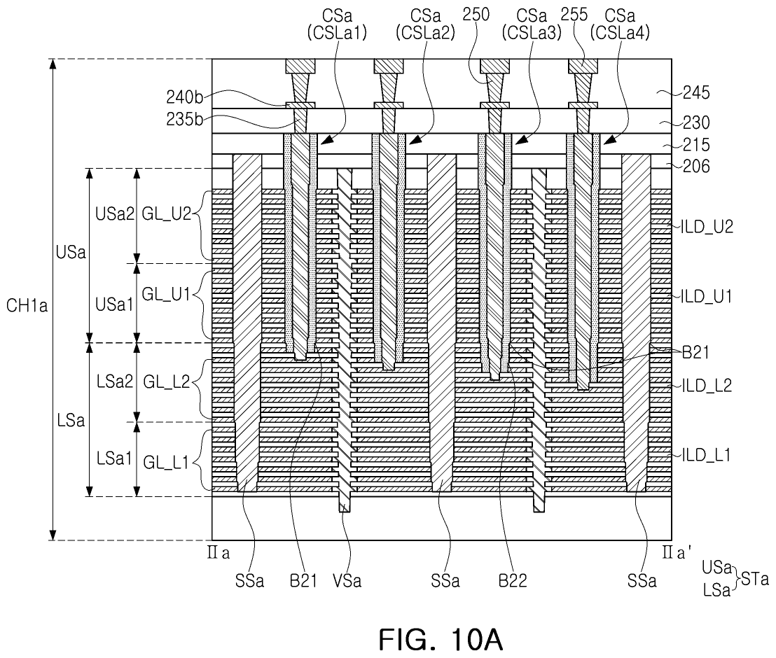

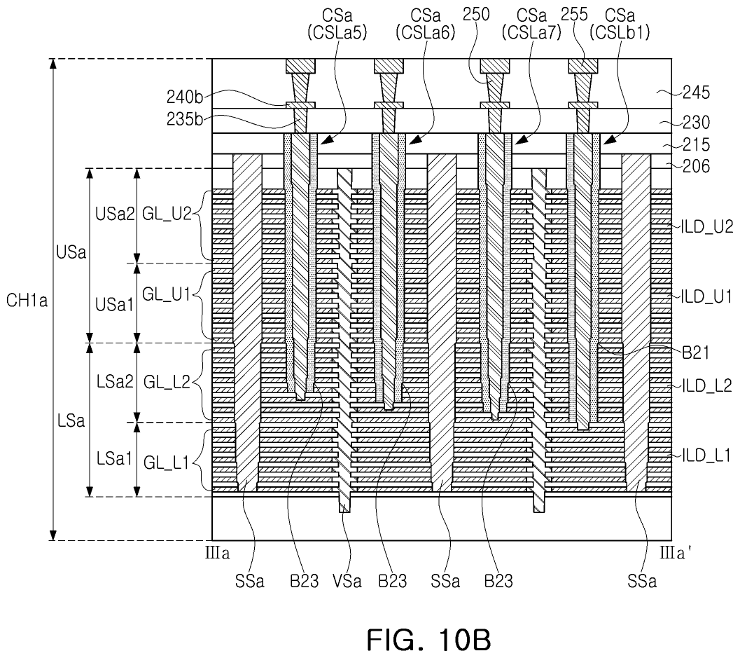

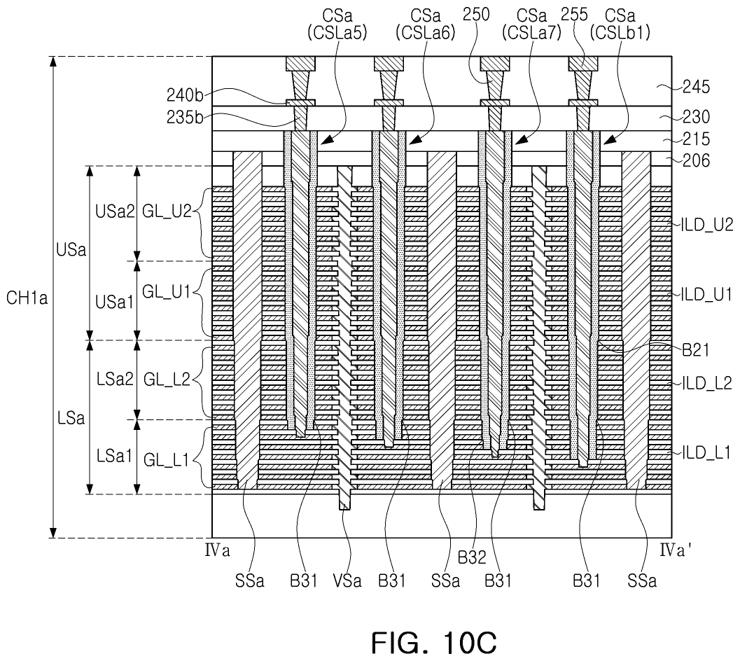

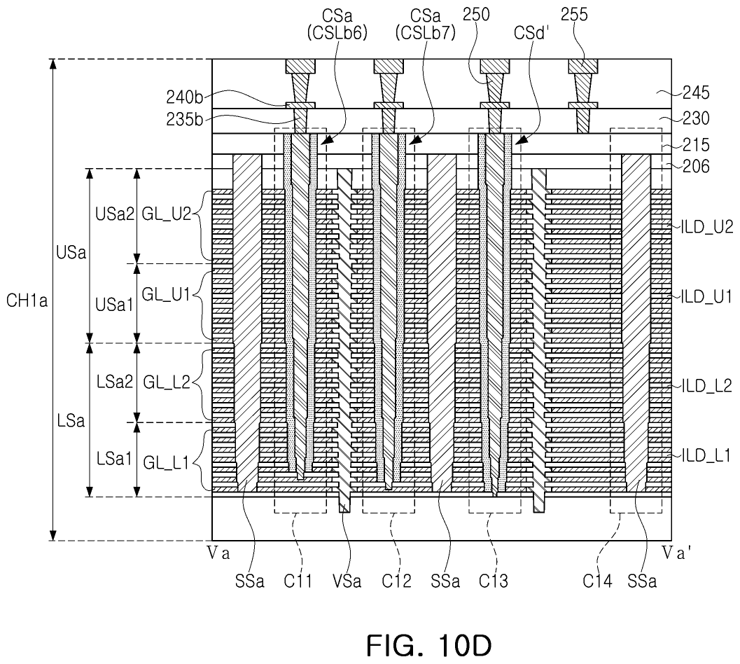

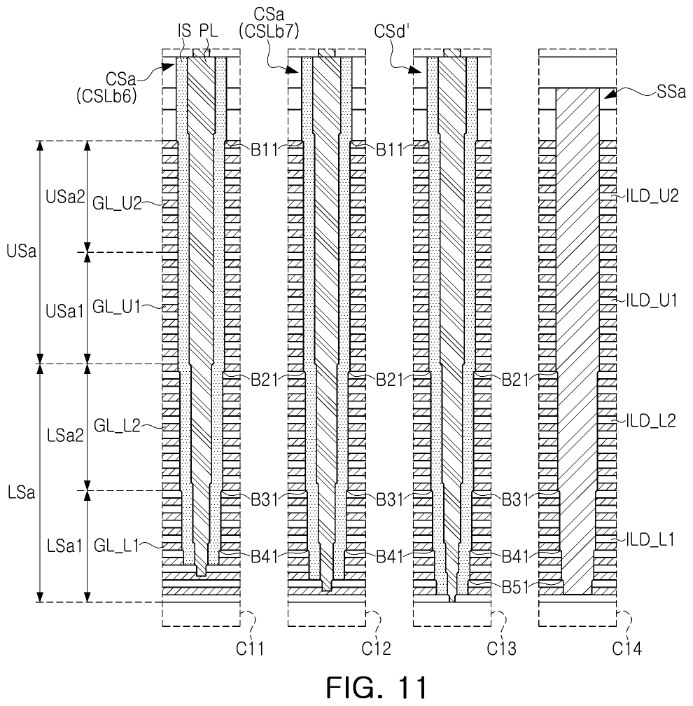

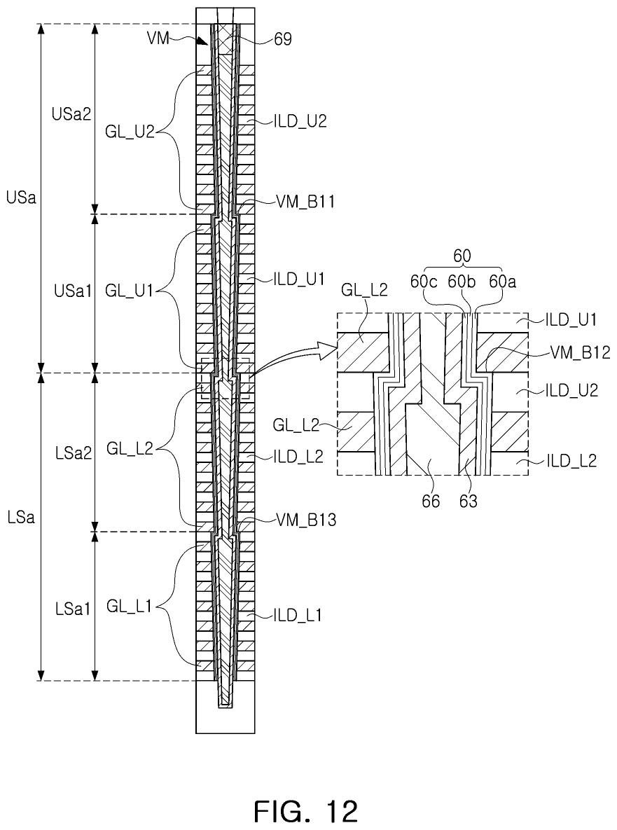

With reference to FIGS. 8 to 12, a first chip structure CH1a that may replace the first chip structure CH1 described above will be described. In FIGS. 8, 9, 10A to 10D, 11 and 12, FIG. 8 is a top view illustrating a semiconductor device according to an embodiment of the present inventive concept, FIG. 9 is a cross-sectional view illustrating a region taken along line Ia-Ia′ of FIG. 8, FIG. 10A is a cross-sectional view illustrating a region taken along line IIa-IIa′ of FIG. 8, FIG. 10B is a cross-sectional view illustrating a region taken along line IIIa-IIIa′ of FIG. 8, FIG. 10C is a cross-sectional view illustrating a region taken along line IVa-IVa′ of FIG. 8, FIG. 10D is a cross-sectional view illustrating a region taken along line V-V′ of FIG. 8, and FIG. 11 is partially enlarged views illustrating regions indicated by C11, C12, C13 and C14.

Referring to FIGS. 8, 9, 10A to 10D, 11 and 12, the lower stack region LS described above may be modified to be a lower stack region LSa including a first lower stack region LSa1 and a second lower stack region LSa2 on the first lower stack region LSa1.

The first lower stack region LSa1 may include lower insulating layers ILD_L1 and lower gate layers GL_L1 that are alternately stacked. The second lower stack region LSa2 may include lower insulating layers ILD_L2 and lower gate layers GL_L2 that are alternately stacked.

The upper stack region US described above may be modified to be an upper stack region USa including a first upper stack region USa1 and a second upper stack region USa2 on the first upper stack region USa1.

The first upper stack region USa1 may include upper insulating layers ILD_U1 and upper gate layers GL_U1 that are alternately stacked. The second upper stack region USa2 may include upper insulating layers ILD_U2 and upper gate layers GL_U2 that are alternately stacked.

Accordingly, the stack structure ST described above may be modified to be a stack structure STa including the lower and upper stack regions LSa and USa.

The vertical channel structure VM described above may be modified to be a vertical channel structure VM1 penetrating the stack structure Sta and including a channel bending portion VM_B11 between the second upper stack region USa2 and the first upper stack region USa1, a channel bending portion VM_B12 between the second lower stack region LSa2 and the first upper stack region USa1, and a channel bending portion VM_B13 between the second lower stack region LSa2 and the first lower stack region LSa1. The vertical channel structure VM1 may include the channel layer 63, the insulating core region 66, the data storage structure 60 and the pad pattern 69 described above.

The vertical support structure VS described above may be modified to be a vertical support structure VSa penetrating the stack structure STa.

Capping insulating layers 206, 215, 230 and 245 corresponding to the capping insulating layers 106, 115, 130 and 145, respectively, described above, may be disposed on the stack structure STa.

Contact plugs 235a and 235b, a bit line 240a, a gate interconnection structure 240b, an interconnection structure 250 and first bonding pads 225 corresponding to the contact plugs 135a and 135b, the bit line 140a, the gate interconnection structure 140b, the interconnection structure 150 and the first bonding pads 155, respectively, described above, may be disposed on the stack structure STa.

The gate contact structures CS, the additional contact structures CSd and the separation structures SS described above may be modified to be a gate contact structures CSa, additional contact structures CSd′ and a separation structures SSa illustrated in FIGS. 8 to 11.

Similar to those described above, each of the gate contact structures CSa may include a conductive contact plug PL and an insulating spacer IS on a side surface of the conductive contact plug PL.

The gate contact structures CSa may include upper gate contact structures CSUa1 to CSUa3 connected to the upper gate layers GL_U2 of the second upper stack region USa2, upper gate contact structures CSUb1 and CSUb2 connected to the upper gate layers GL_U1 of the first upper stack region USa1, lower gate contact structures CSLa1 to CSLa7 connected to the lower gate layers GL_L2 of the second lower stack region LSa2, and lower gate contact structures CSLb1 to CSLb7 connected to the lower gate layers GL_L1 of the first lower stack region LSa1.

The gate contact structures CSa may include a contact bending portion B11.

The gate contact structure CSUa2 may further include a contact bending portion B12.

The gate contact structure CSUa3 may further include a contact bending portion B13 and a contact bending portion B14.

The gate contact structure CSUb1 may further include a contact bending portion B15 and a contact bending portion B16.

The gate contact structure CSUb2 may further include a contact bending portion B15, a contact bending portion B17 and a contact bending portion B18.

The gate contact plugs CSLa1 to CSLa7 and CSLb1 to CSLb7 may further include a contact bending portion B21.

The CSLa3 gate contact structure may further include a contact bending portion B22.

The gate contact structures CSLa5, CSLa6 and CSLa7 may further include a contact bending portion B23.

The gate contact structures CSLb2, CSLb3, CSLb4, CSLb5, CSLb6 and CSb7 may further include a contact bending portion B31.

The gate contact structure CSLb4 may further include a contact bending portion B32.

The gate contact structures CSLb6 and CSb7 may further include a contact bending portion B41.

The gate contact structure CSd′ may include the contact bending portions B11, B21, B31, B41, and B51.

The separation structures SSa may include separation bending portions B21, B31, B41 and B51 corresponding to contact the bending portion B21, B31, B41, and B51.

In the gate contact structure CSLb7, a side surface of a first lower contact portion positioned at a level lower than that of the upper stack region USa may include N lower bending portions, and in the gate contact structure CSLa5, a side surface of a second lower contact portion positioned at a level lower than that of the upper stack region USa may include M lower bending portions, where N may be a natural number, M may be 0 or a natural number, and N may be greater than M. For example, in the gate contact structure CSLb7, the side surface of the first lower contact portion positioned at a level lower than that of the upper stack region USa may include two (2) lower bending portions B31 and B41, and in the gate contact structure CSLa5, the side surface of the second lower contact portion positioned at a level lower than that of the upper stack region USa may include one (1) lower bending portion B23.

The separation structure SSa comprises an upper separation portion penetrating the upper stack region USa and a lower separation portion extending from the upper separation portion and penetrating the lower stack region LSa, a side surface of the separation structure SSa may include a separation bending portion B21, bent from a side surface of the upper separation portion and extending to a side surface of the lower separation portion, at least a portion of the separation bending portion B21 may be disposed at substantially the same level as at least a portion of the contact bending portion B21 and at least a portion of the second channel bending portion VM_B12. The side surface of the lower separation portion may include K lower separation bending portions. In an embodiment, K is a natural number equal to or greater than N.

At a height level between a lowermost lower gate layer of the lower gate layers GL_L1 and an uppermost upper gate layer of the upper gate layers GL_U2, a side surface of the vertical channel structure VM1 may include X channel bending portions, and a side surface of the first lower gate contact structure may include Y contact bending portions, where X and Y may be natural numbers greater than 2. For example, the side surface of the vertical channel structure VM1 may include a channel bending portion VM_B11, a channel bending portion VM_B12 and a channel bending portion VM_B13, disposed at different levels from each other, and the side surface of the lower gate contact structure CSLb7 may include a contact bending portion B21, a contact bending portion B31 and a contact bending portion B41, disposed at different levels from each other, and at least a portion of the contact bending portion B21 may be disposed at the same level as at least a portion of the channel bending portion VM_B12. The channel bending portion VM_B11 may be disposed at a level lower than that of the channel bending portion VM_B12, the channel bending portion VM_B13 may be disposed at a level higher than that of the channel bending portion VM_B12, and the contact bending portion B31 and the contact bending portion B41 may be disposed at a level lower than that of the contact bending portion B21. At least one of the contact bending portion B31 and the contact bending portion B41 may be disposed at a different level from the channel bending portion VM_B11.

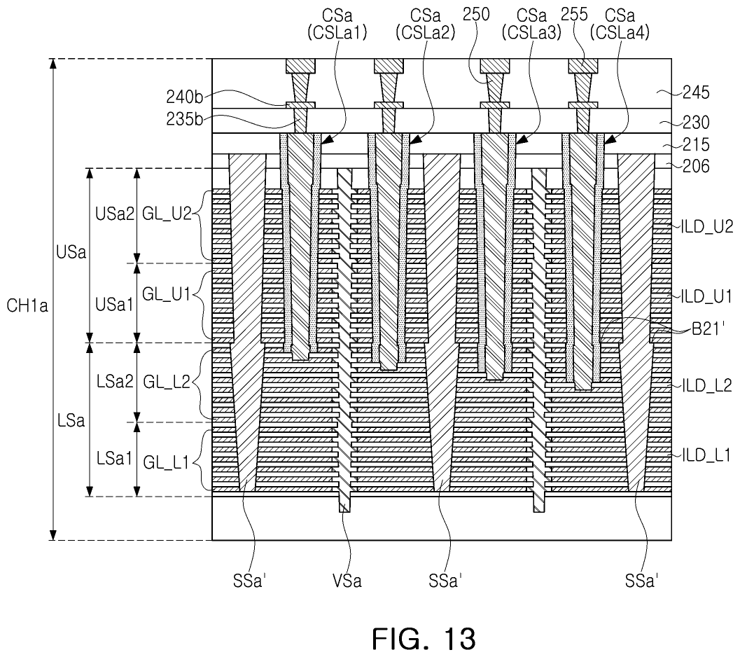

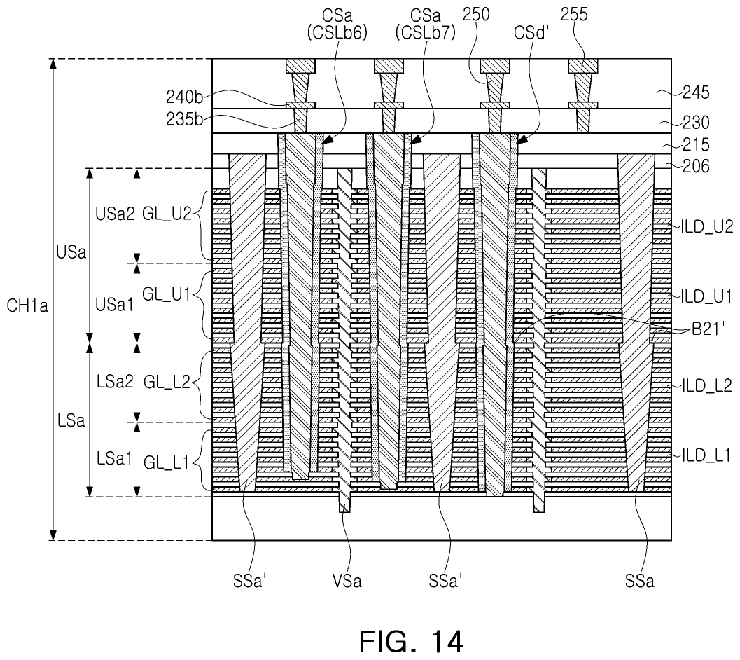

With reference to FIGS. 13 and 14, a first chip structure CH1a that may replace the first chip structure CH1 described above will be described. FIG. 13 is a cross-sectional view illustrating a region taken along line IIa-IIa′ of FIG. 8, and FIG. 14 is a cross-sectional view illustrating a region area taken along the line Va-Va′ in FIG. 8.

Referring to FIGS. 13 and 14, the separation structures SSa described above may be modified to be a separation structures SSa′ including a separation bending portion B21′ whose width changes in a boundary region between the lower stack region LSa and the upper stack region USa. For example, in each of the separation structures SSa′, a width (i.e., a first width) of an upper region of a portion penetrating the lower stack region LSa may be greater than a width (i.e., a second width) of a lower region of a portion penetrating the upper stack region USa. Accordingly, side surfaces of the separation structures SSa′ may include the separation bending portion B21′, bent from a side surface of the portion penetrating the lower stack region LSa and a side surface of the portion penetrating the upper stack region USa. For example, the bending portion B21′ may have a decreasing width from the first width to the second width.

The lower gate contact structures described above may be modified to be lower gate contact structures including a contact bending portion B21′ whose width changes in a boundary region between the lower stack region LSa and the upper stack region USa. For example, in gate contact structures CSLa1′, CSLa2′, CSLa3′, CSLa4′, CSLa5′, CSLa6′ CSLa7′ and contact structure CSd″, a width (i.e., a first width) of the lower region of the portion penetrating the upper stack reason USa may be less than a width (i.e., a second width) of a portion positioned on the lower stack region LSa adjacent to the upper stack region USa. Accordingly, side surfaces of the gate contact structures CSLa1′, CSLa2′, CSLa3′, CSLa4′, CSLa5′, CSLa6′ and CSLa7′ and the contact structure CSd″ may include the contact bending portion B21′, bent from the side surface of the portion penetrating the upper stack region USa and extends therefrom. For example, the contact bending portion B21′ may have a decreasing width from the second width to the first width.

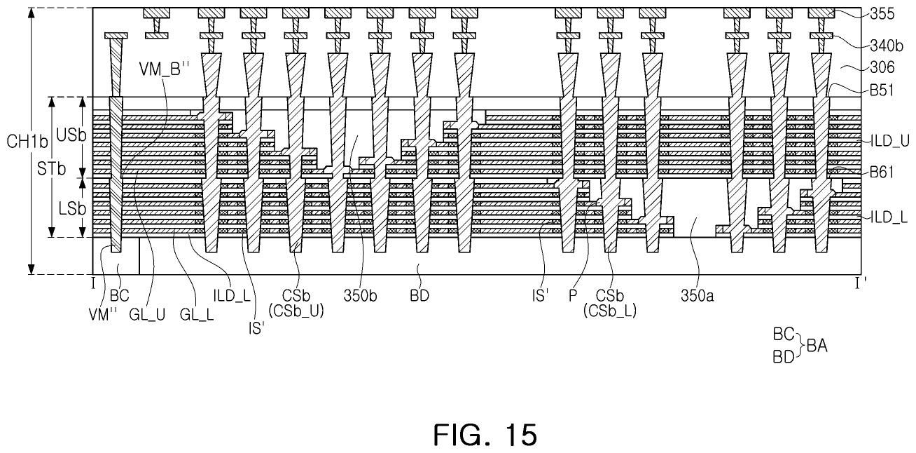

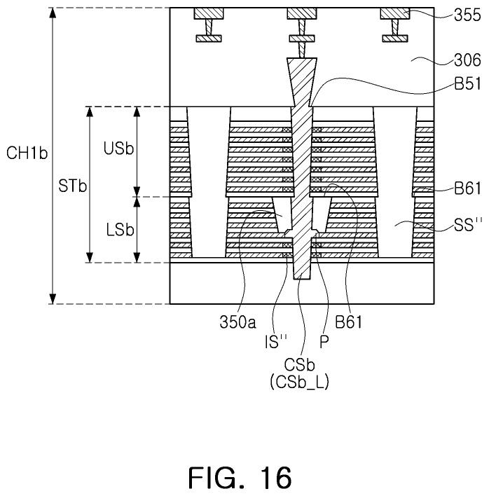

With reference to FIGS. 15 and 16, a first chip structure CH1b that may replace the first chip structure CH1 described above will be described. FIG. 15 is a diagram illustrating a cross-sectional structure taken in a first horizontal direction to illustrate a semiconductor device according to an embodiment of the present inventive concept, and FIG. 16 is a diagram illustrating a cross-sectional structure taken in a second horizontal direction perpendicular to the first horizontal direction to illustrate a semiconductor device according to an embodiment of the present inventive concept.

Referring to FIGS. 15 and 16, a stack structure STb may be disposed on the base BA as described above. The stack structure STb may include a lower stack region LSb and an upper stack region USb on the lower stack region LSb.

The lower stack region LSb may include lower gate layers GL_L and lower interlayer insulating layers ILD_L that are alternately stacked in a vertical direction. The upper stack region USb may include upper gate layers GL_U and upper interlayer insulating layers ILD_U that are stacked in the vertical direction. The lower stack region LSb may include lower gate contact regions arranged in a stepped shape of the lower gate layers GL_L, and the upper stack region USb may include upper gate contact regions arranged in a stepped shape of the upper gate layers GL_U.

A lower capping insulating layer 350a covering the lower gate contact regions arranged in a stepped shape of the lower stack region LSb and an upper capping insulating layer 350b covering the upper gate contact regions arranged in a stepped shape of the upper stack region USb may be disposed.

A vertical channel structure VM which is substantially the same as that described above may be disposed. The vertical channel structure VM may penetrate the stack structure STb. The vertical channel structure VM may include a channel bending portion VM_B″ between the lower stack region LSb and the upper stack region USb.

Gate contact structures CSb may be disposed. The gate contact structures CSb may include upper gate contact structures CSb_U connected to the upper gate contact regions arranged in a stepped shape of the upper gate layers GL_U and lower gate contact structures CSb_L connected to the lower gate contact regions arranged in a stepped shape of the lower gate layers GL_L.

Side surfaces of the gate contact structures CSb may include a contact bending portion B61 including a portion disposed at the same level as at least a portion of the channel bending portion VM_B″.

Among the gate layers GL_L and GL_U, insulting spacers IS′ may be disposed between the gate contact structures CSb and the gate layers GL_L and GL_U adjacent but not connected to the gate contact structures CSb. Accordingly, one of the gate contact structures CSb may be electrically connected to one gate layer and electrically separated from other gate layers by the insulating spacers IS′.

The side surfaces of the gate contact structures CSb may include an upper contact bending portion B51 at a level higher than that of the upper gate layers GL_U.

Separation structures SS″ penetrating the stack structure STb may be disposed. Side surfaces of the separation structures SS″ may include a separation bending portion B61 disposed at substantially the same level as the contact bending portion B61.

Upper surfaces of the gate contact structures CSb may be disposed at a level higher than that of upper surfaces of the separation structures SS″.

Interconnection structures 340a and 340b may be disposed on the vertical channel structure VM″ and the gate contact structures CSb. First bonding pads 355 may be disposed on the interconnection structures 340a and 340b. The first bonding pads 355 may have an upper surface coplanar with the upper surface of the insulating structure 306 disposed on the stack structure STb.

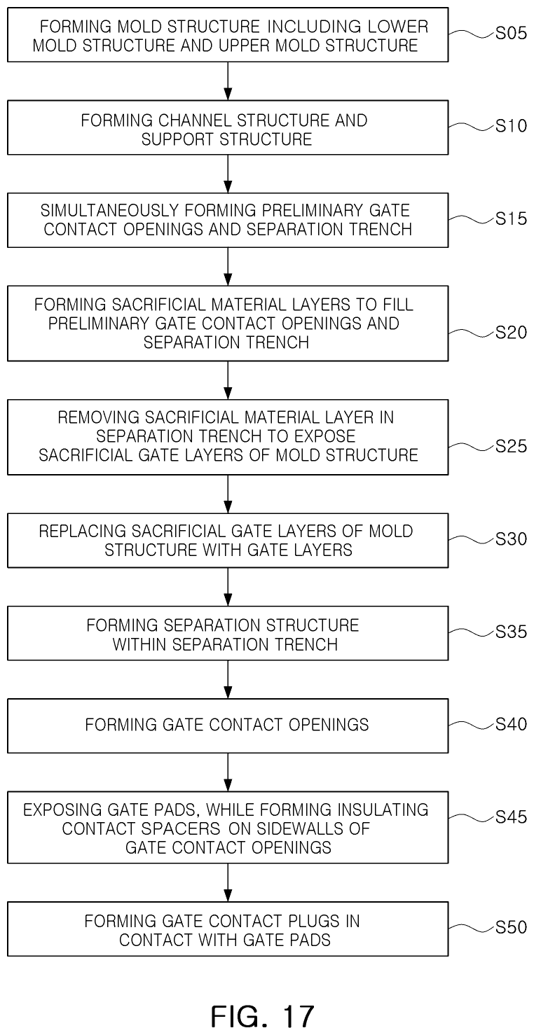

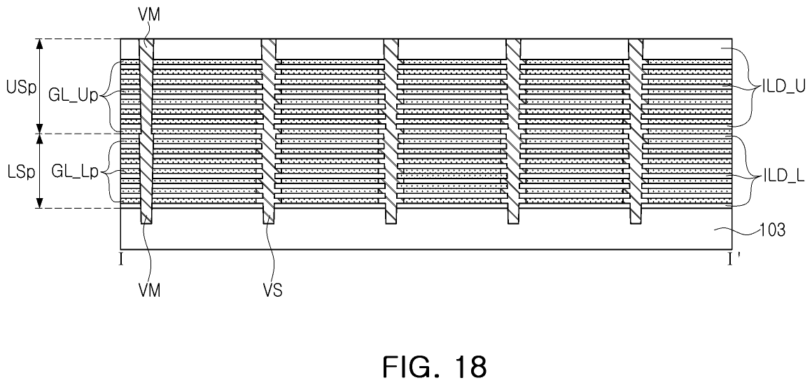

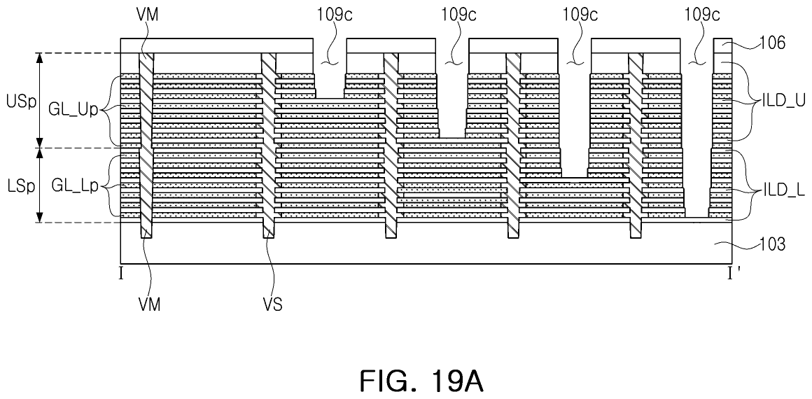

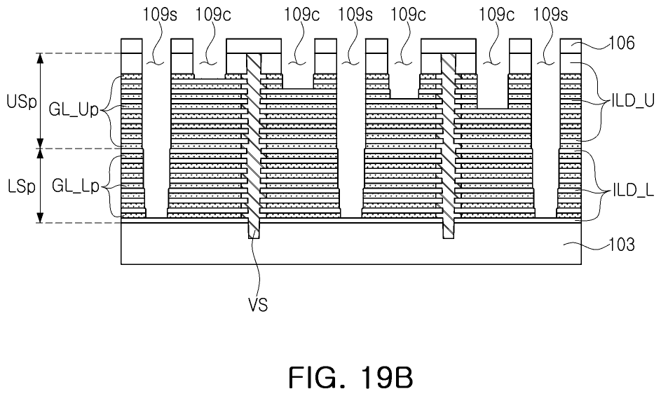

Next, with reference to FIGS. 17, 18, 19A, 19B, 20A, 20B, 21A, 21B, 22A, 22B, 23A and 23B, an example of a method of forming a semiconductor device according to an embodiment of the present inventive concept will be described. FIG. 17 is a process flowchart for illustrating an example of a method of forming a semiconductor device according to an embodiment of the present inventive concept, and FIGS. 18, 19A, 19B, 20A, 20B, 21A, 21B, 22A, 22B, 23A and 23B are cross-sectional views for illustrating a method of forming a semiconductor device according to an embodiment of the present inventive concept. FIGS. 18, 19A, 20A, 21A, 22A and 23A are cross-sectional views illustrating regions taken along line I-I′ of FIG. 1, and FIGS. 19B, 20B, 21B, 22B and 23B are cross-sectional views illustrating regions taken along line II-II′ in FIG. 1.

Referring to FIGS. 17 and 18, a mold structure including a lower mold structure LSp and an upper mold structure USp may be formed (S05). The mold structures LSp and USp may be formed on a carrier substrate 103. The upper mold structure USp may be disposed on the lower mold structure LSp. The lower mold structure LSp may include interlayer insulating layers ILD_L and sacrificial gate layers GL_Lp that are alternately stacked. The upper mold structure USp may include interlayer insulating layers ILD_U and sacrificial gate layers GL_Up that are alternately stacked.

A channel structure VM and a support structure VS can be formed (S10). The channel structure VM and the support structure VS may penetrate the mold structures LSp and USp.

Referring to FIGS. 17, 19A and 19B, a first capping insulating layer 106 may be formed on the mold structures LSp and USp.

Preliminary gate contact openings 109c and a separation trench 109s may be formed simultaneously (S15). The preliminary gate contact openings 109c may have lower surfaces located at different heights from each other.

Forming the preliminary gate contact openings 109c and the separation trench 109s may include simultaneously forming the preliminary gate contact openings 109c having the lower surfaces located at different heights from each other and the separation trench 109s, while repeating a unit process of a photo process and an etching process.

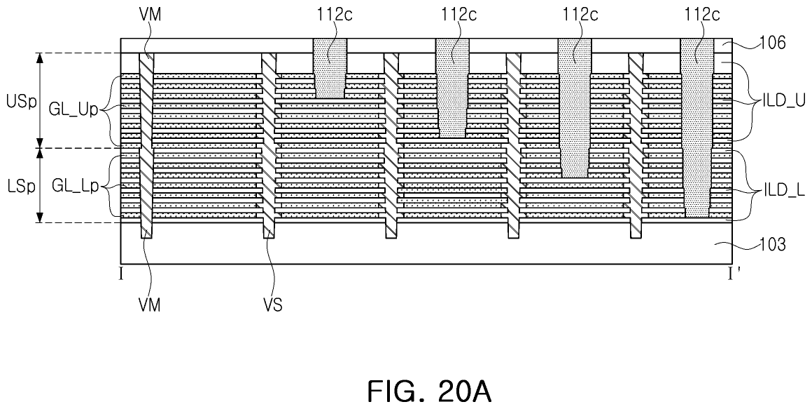

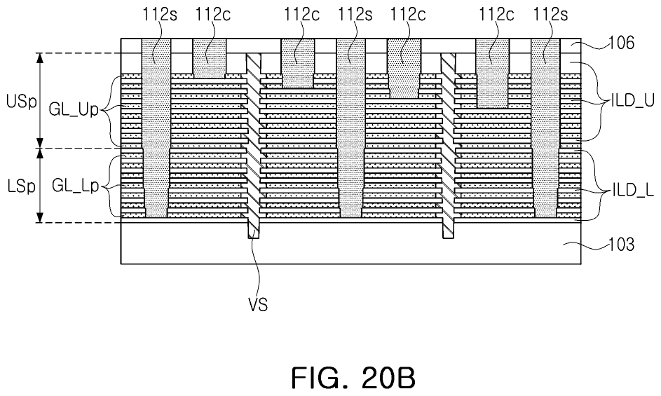

Referring to FIGS. 17, 20A and 20B, sacrificial material layers 112c and 112s may be formed to fill the preliminary gate contact openings 109c and the separation trench 109s (S20).

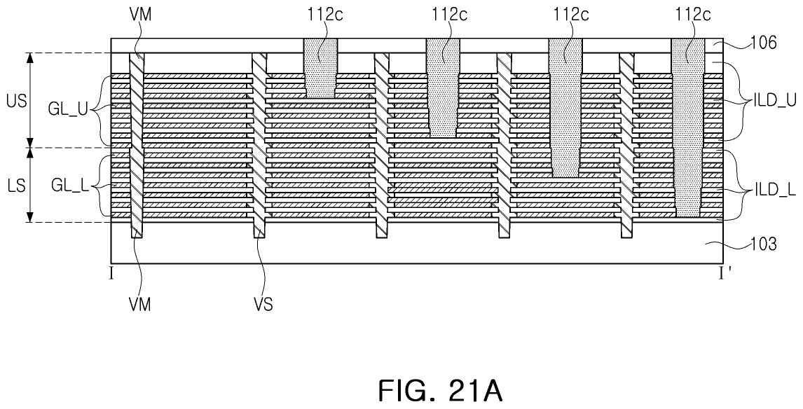

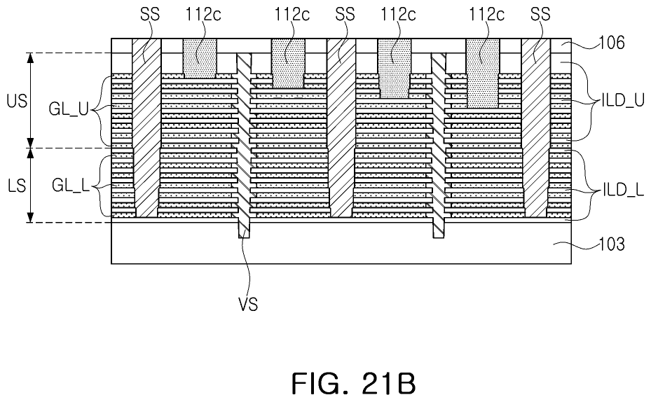

Referring to FIGS. 17, 21A, and 21B, the sacrificial material layer 112s in the separation trench 109s may be removed to expose sacrificial gate layers GL_Lp and GL_Up of the mold structure LSp and USp (S25).

The sacrificial gate layers GL_Lp and GL_Up of the mold structure LSp and USp may be replaced with gate layers GL_L and GL_U (S30).

A separation structure SS may be formed within the separation trench 109s (S35).

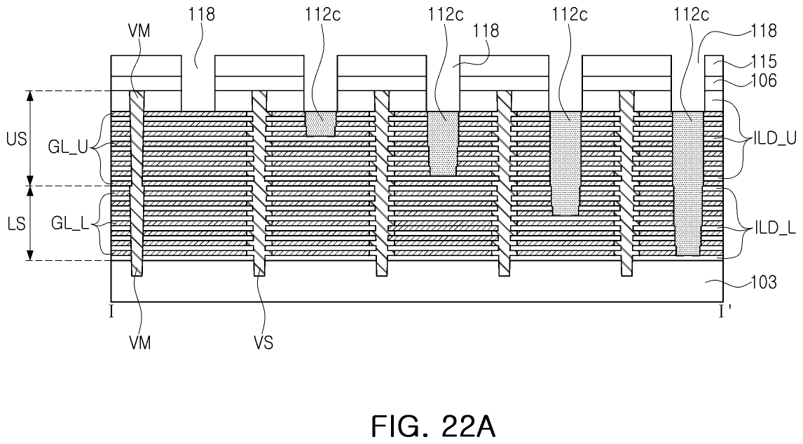

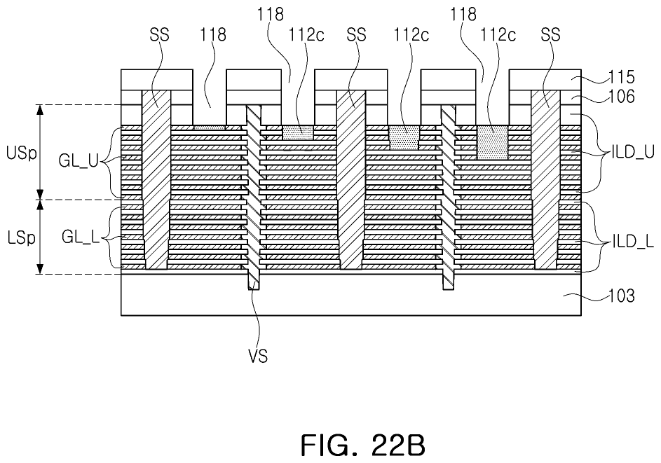

Referring to FIGS. 17, 22A, and 22B, a second capping insulating layer 115 may be formed on the first capping insulating layer 106.

Openings 118 penetrating the first and second capping insulating layers 106 and 115, and an uppermost interlayer insulating layer ILD_U of the interlayer insulating layers may be formed.

The sacrificial material layers 112c within the preliminary gate contact openings 109c may be exposed through the openings 118.

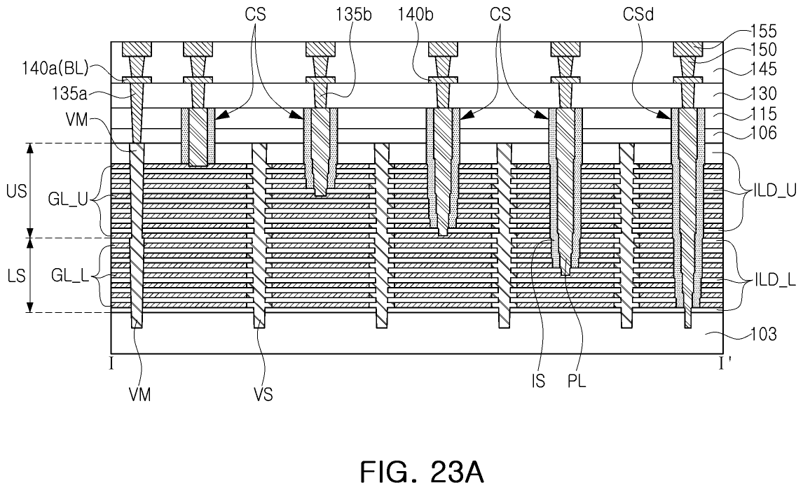

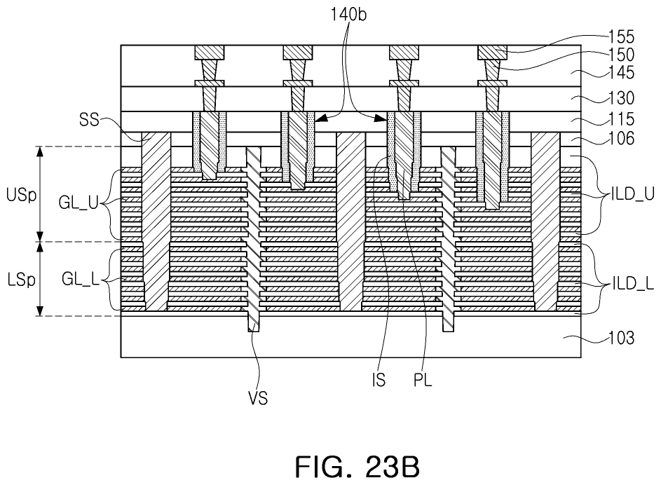

Referring to FIGS. 17, 23A, and 23B, gate contact openings may be formed (S40). Forming the gate contact openings may include removing the sacrificial material layers 112c within the preliminary gate contact openings 109c exposed through the openings 118.

Gate pads may be exposed, while forming insulating contact spacers IS on sidewalls of the gate contact openings (S45). The gate pads may be gate contact regions of the gate layers GL_L and GL_U. Gate contact plugs PL in contact with the gate pads may be formed (S50). Accordingly, gate contact structures CS including the insulating spacer IS and the contact plug PL may be formed.

A third capping insulating layer 130 may be formed to cover the gate contact structures CS. Subsequently, an interconnection process can be performed. For example, contact plugs 135a and 135b connected to the vertical channel structure VM and the gate contact structures CS, interconnection structures 140a and 140b on the contact plugs 135a and 135b, an interconnection structure 150 on the interconnection structures 140a and 140b, and first bonding pads 155 having upper surfaces coplanar with an upper surface of a fourth capping insulating layer 145 on the interconnection structure 150 may be formed.

Referring to FIGS. 1 to 6, a second chip structure CH2 including a peripheral circuit may be formed. By performing a wafer bonding process, a structure formed up to the first bonding pads 155 corresponding to the resulting structure of FIGS. 23A and 23B may be bonded to the second bonding pads 25 of the second chip structure CH2. Subsequently, a process of replacing the carrier substrate 103 with a base BA may be performed.

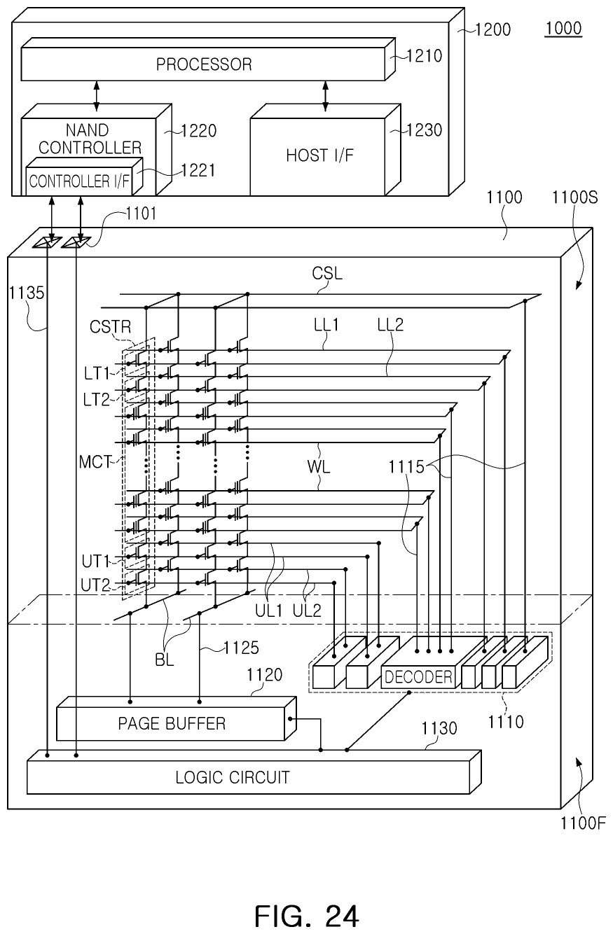

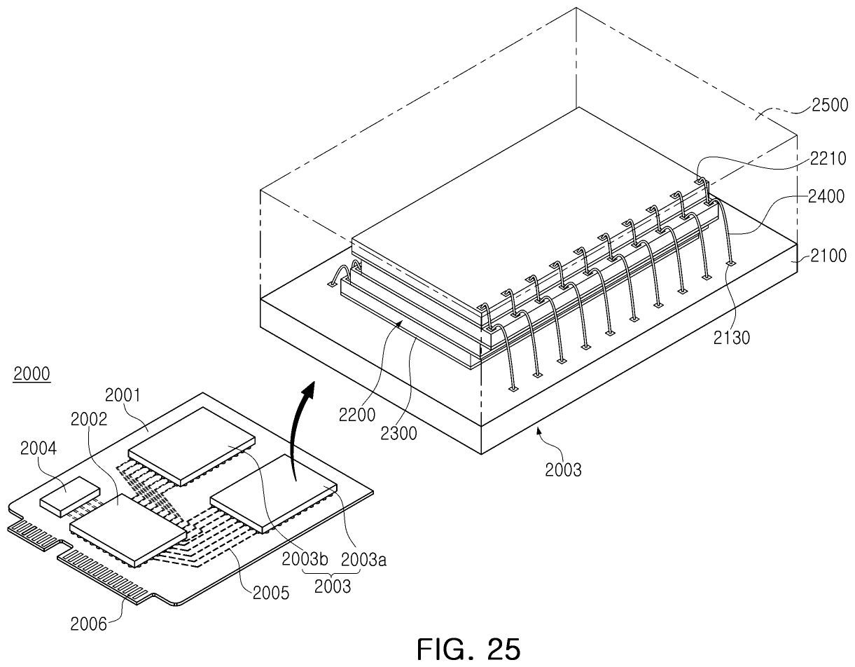

Next, a data storage system including a semiconductor device according to an exemplary embodiment will be described with reference to FIGS. 24 and 25.

FIG. 24 is a diagram schematically illustrating a data storage system including a semiconductor device according to an exemplary embodiment of the present inventive concept.

Referring to FIG. 24, a data storage system 1000 according to an exemplary embodiment of the present inventive concept may include a semiconductor device 1100 and a controller 1200 electrically connected to the semiconductor device 1100 to control the semiconductor device 1100. The data storage system 1000 may be implemented as a storage device including the semiconductor device 1100 or an electronic device including the storage device. For example, the data storage system 1000 may be implemented as a solid state drive (SSD) device, a universal serial bus (USB), a computing system, a medical device, or a communication device, including one or a plurality of semiconductor devices 1100.

In an embodiment, the data storage system 1000 may be configured as an electronic system that stores data.

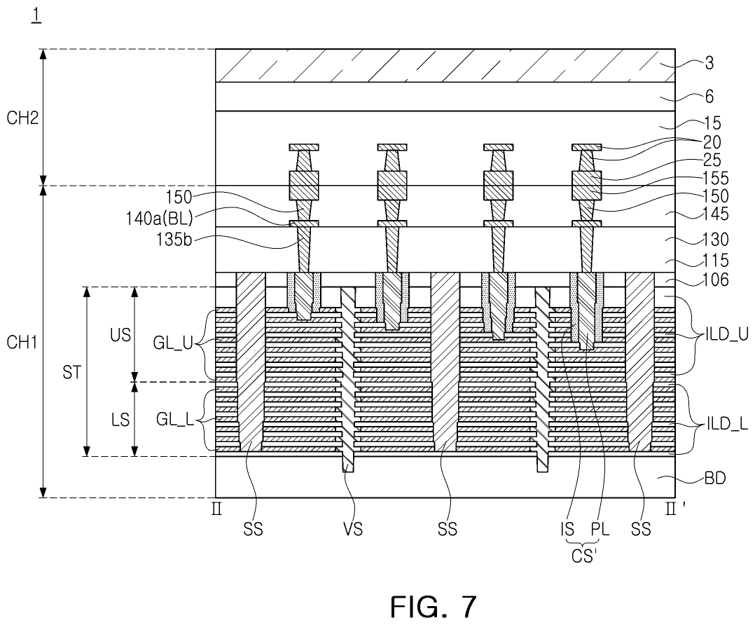

The semiconductor device 1100 may be implemented as a non-volatile memory device. For example, the semiconductor device 1100 may be configured as the semiconductor device according to one of the embodiments described above with reference to FIGS. 1 to 16. The semiconductor device 1100 may include a first structure 1100F and a second structure 1100S on the first structure 1100F.

The first structure 1100F may be implemented as a peripheral circuit structure including a decoder circuit 1110, a page buffer 1120 and a logic circuit 1130. For example, the first structure 1100F may include the peripheral circuit structure described above. The peripheral elements (PTR in FIG. 2) described above may be implemented as a transistor that may configure a decoder circuit 1110, a page buffer 1120 and a logic circuit 1130.

The second structure 1100S may be implemented as a memory structure including bit lines BL, a common source lines CSL, word lines WL, first and second upper gate lines UL1 and UL2, first and second lower gate lines LL1 and LL2 and memory cell strings CSTR disposed between the bit lines BL and the common source line CSL.

In the second structure 1100S, each of the memory cell strings CSTR may include lower transistors LT1 and LT2 adjacent to the common source line CSL, upper transistors UT1 and UT2 adjacent to the bit line BL, and a plurality of memory cell transistors MCT disposed between the lower transistors LT1 and LT2 and the upper transistors UT1 and UT2. The number of lower transistors LT1 and LT2 and the number of upper transistors UT1 and UT2 may be varied in the embodiments.

The plurality of memory cell transistors MCT may include the gate layers GL_L and GL_U described above, which may be word lines, the channel layer 63 and the data storage structure 60.

In the exemplary embodiments, the upper transistors UT1 and UT2 may include a string select transistor, and the lower transistors LT1 and LT2 may include a ground select transistor. The lower gate lines LL1 and LL2 may be configured as gate electrodes of the lower transistors LT1 and LT2, respectively. The word lines WL may be configured as gate electrodes of the memory cell transistors MCT, and the upper gate lines UL1 and UL2 may be configured as gate electrodes of the upper transistors UT1 and UT2, respectively.

The gate layers GL_L and GL_U may include the lower gate lines LL1 and LL2, the word lines WL and the upper gate lines UL1 and UL2.

The common source line CSL, the first and second lower gate lines LL1 and LL2, word lines WL, and the first and second upper gate lines UL1 and UL2 may be electrically connected to the decoder circuit 1110 through first connection lines 1115 extending from the first structure 1100F to the second structure 1100S.

The bit lines BL may be electrically connected to the page buffer 1120 through second connection lines 1125 extending from the first structure 1100F to the second structure 1100S.

In the first structure 1100F, the decoder circuit 1110 and the page buffer 1120 may perform a control operation on at least one memory cell transistor MCT selected from the plurality of memory cell transistors MCT. The decoder circuit 1110 and the page buffer 1120 may be controlled by the logic circuit 1130.

The semiconductor device 1000 may further include an input/output pad 1101. The semiconductor device 1100 may communicate with the controller 1200 through the input/output pad 1101 electrically connected to the logic circuit 1130. The input/output pads 1101 may be electrically connected to the logic circuit 1130 through an input/output connection line 1135 extending from the first structure 1100F to the second structure 1100S. Accordingly, the controller 1200 may be electrically connected to the semiconductor device 1000 through the input/output pad 1101 and may control the semiconductor device 1000.

The input/output pad 1101 may be an input/output pad.

The controller 1200 may include a processor 1210, a NAND controller 1220 and a host interface 1230. In the embodiments, the data storage system 1000 may include a plurality of semiconductor devices 1100, and in this case, the controller 1200 may control the plurality of semiconductor devices 1100.

The processor 1210 may control overall operations of the data storage system 1000 including the controller 1200. The processor 1210 may operate according to a predetermined firmware, and may access the semiconductor device 1100 by controlling the NAND controller 1220. The NAND controller 1220 may include a controller interface 1221 processing communication with the semiconductor device 1100. Through the controller interface 1221, a control command for controlling the semiconductor device 1100, data to be written to the memory cell transistors MCT of the semiconductor device 1100, data to be read from the memory cell transistors MCT of the semiconductor device 1100 or the like may be transmitted. The host interface 1230 may provide a communication function between the data storage system 1000 and an external host. When a control command from the external host is received through the host interface 1230, the processor 1210 may control the semiconductor device 1100 in response to the control command.

FIG. 25 is a perspective diagram schematically illustrating a data storage system including a semiconductor device according to an exemplary embodiment.

Referring to FIG. 25 a data storage system 2000 in an exemplary embodiment may include a main board 2001, a controller 2002 mounted on the main board 2001, one or more semiconductor packages 2003, and a dynamic random access memory (DRAM) 2004. The semiconductor package 2003 and the DRAM 2004 may be connected to the controller 2002 by interconnection patterns 2005 formed on the main board 2001.

The main board 2001 may include a connector 2006 including a plurality of pins to be coupled to an external host. The number and arrangement of the plurality of pins in the connector 2006 may vary depending on a communication interface between the data storage system 2000 and the external host. In the exemplary embodiments, the data storage system 2000 may communicate with an external host according to any one of interfaces, such as universal serial bus (USB), peripheral component interconnect express (PCI-Express), serial advanced technology attachment (SATA), M-Phy for universal flash storage (UFS), and the like. In the exemplary embodiments, the data storage system 2000 may operate by power supplied from an external host through the connector 2006. The data storage system 2000 may further include a power management integrated circuit (PMIC) for distributing power supplied from the external host to the controller 2002 and the semiconductor package 2003.

The controller 2002 may write data to or may read data from the semiconductor package 2003, and may improve an operating speed of the data storage system 2000.

The DRAM 2004 may be configured as a buffer memory for alleviating a difference in speeds between the semiconductor package 2003, which is a data storage space, and an external host. The DRAM 2004 included in the data storage system 2000 may operate as a cache memory, and may provide a space for temporarily storing data in a control operation for the semiconductor package 2003. When the data storage system 2000 includes the DRAM 2004, the controller 2002 may further include a DRAM controller for controlling the DRAM 2004 in addition to a NAND controller for controlling the semiconductor package 2003.

The semiconductor package 2003 may include first and second semiconductor packages 2003a and 2003b spaced apart from each other. Each of the first and second semiconductor packages 2003a and 2003b may be configured as a semiconductor package including a plurality of semiconductor chips 2200. Each of the semiconductor chips 2200 may include the semiconductor device according to the embodiments described above with reference to FIGS. 1 to 16.

Each of the first and second semiconductor packages 2003a and 2003b may include a package substrate 2100, semiconductor chips 2200 on the package substrate 2100, adhesive layers 2300 disposed on lower surfaces of the semiconductor chips 2200, a connection structure 2400 electrically connecting the semiconductor chips 2200 to the package substrate 2100, and a molding layer 2500 covering the semiconductor chips 2200 and the connection structure 2400 on the package substrate 2100.

The package substrate 2100 may be configured as a printed circuit board including package upper pads 2130. Each of the semiconductor chips 2200 may include an input/output pad 2210.

In the exemplary embodiments, the connection structure 2400 may be configured as a bonding wire electrically connecting the input/output pad 2210 to the package upper pads 2130. Accordingly, in each of the first and second semiconductor packages 2003a and 2003b, the semiconductor chips 2200 may be electrically connected with each other by a bonding wire method, and may be electrically connected to the package upper pads 2130 of the package substrate 2100. In the example embodiments, in each of the first and second semiconductor packages 2003a and 2003b, the semiconductor chips 2200 may be electrically connected with each other by a connection structure including a through-electrode (TSV) instead of the connection structure 2400 of a bonding wire method.

In the exemplary embodiments, the controller 2002 and the semiconductor chips 2200 may be included in a single package. For embodiment, the controller 2002 and the semiconductor chips 2200 may be mounted on an interposer substrate different from the main board 2001, and the controller 2002 and the semiconductor chips 2200 may be connected with each other by interconnection formed on the interposer substrate. In the semiconductor package 2003, the package substrate 2100 may be implemented as a printed circuit board. Each of the semiconductor chips 2200 may be the semiconductor device according to the embodiments described above with reference to FIGS. 1 to 16

According to the embodiments, gate contact structures contacting contact regions of gate layers may be formed through a gate contact plug forming process without a separate stepping process to form the contact regions of the gate layers in a stepped shape. Accordingly, the process of forming the contact regions of the gate layers in a stepped shape can be omitted, and an area occupied by the contact regions in a stepped shape can be reduced, thereby improving the integration of the semiconductor device.

The various and beneficial advantages and effects of the present inventive concept are not limited to the above-described content, and may be more easily understood through description of specific embodiments of the present inventive concept.

While example embodiments have been shown and described above, it will be apparent to those skilled in the art that modifications and variations could be made without departing from the scope of the present inventive concept as defined by the appended claims.

What is claimed is:

1. A semiconductor device, comprising:
a stack structure comprising a lower stack region and an upper stack region on the lower stack region, wherein the lower stack region comprises a plurality of lower gate layers and a plurality of lower interlayer insulating layers alternately stacked in a vertical direction, and the upper stack region comprises a plurality of upper gate layers and a plurality of upper interlayer insulating layers alternately stacked in the vertical direction;
a vertical channel structure penetrating the stack structure in the vertical direction and comprising a data storage structure and a channel layer;
a plurality of lower gate contact structures contacting a plurality of lower gate contact regions of the plurality of lower gate layers, wherein the plurality of lower gate contact structures extend vertically and penetrate the upper stack region; and
a plurality of upper gate contact structures contacting a plurality of upper gate contact regions of the plurality of upper gate layers,
wherein the plurality of upper gate contact structures extend in the vertical direction,
wherein each of the plurality of lower and upper gate contact structures comprises a conductive contact plug and an insulating spacer on a side surface of the conductive contact plug,
wherein a first lower gate contact structure of the plurality of lower gate contact structures comprises a first upper contact portion penetrating the upper stack region, and a first lower contact portion extending downwardly from the first upper contact portion and contacting a first lower gate layer of the plurality of lower gate layers,
wherein a side surface of the first lower gate contact structure comprises a first contact bending portion, bent from a side surface of the first upper contact portion and extending to a side surface of the first lower contact portion,
wherein the vertical channel structure comprises an upper channel portion penetrating the upper stack region, and a lower channel portion extending from the upper channel portion and penetrating the lower stack region,
wherein a side surface of the vertical channel structure comprises a channel bending portion, bent from a side surface of the upper channel portion and extending to a side surface of the lower channel portion, and
wherein at least a portion of the channel bending portion is disposed at the same level as at least a portion of the first contact bending portion.

2. The semiconductor device of claim 1,
wherein the plurality of upper gate layers surround the side surface of the first lower gate contact structure, and
wherein, among the lower gate layers, a lower gate layer disposed at a level higher than the first lower gate layer surrounds the side surface of the first lower gate contact structure.

3. The semiconductor device of claim 1, further comprising:
a separation structure penetrating the stack structure in the vertical direction, wherein the separation structure has a line shape extending in a first horizontal direction perpendicular to the vertical direction,
wherein the separation structure comprises an upper separation portion penetrating the upper stack region and a lower separation portion extending from the upper separation portion and penetrating the lower stack region,
wherein a side surface of the separation structure comprises a separation bending portion, bent from a side surface of the upper separation portion and extending to a side surface of the lower separation portion, and
wherein at least a portion of the separation bending portion is disposed at substantially the same level as the at least a portion of the first contact bending portion.

4. The semiconductor device of claim 3,
wherein a width of the lower separation portion penetrating an uppermost lower gate layer of the plurality of lower gate layers is different from a width of the upper separation portion penetrating a lowermost upper gate layer of the plurality of upper gate layers.

5. The semiconductor device of claim 1,
wherein a second lower gate contact structure of the plurality of lower gate contact structures comprises a second upper contact portion penetrating the upper stack region, and a second lower contact portion extending downwardly from the second upper contact portion and contacting a second lower gate layer of the plurality of lower gate layers,
wherein the second lower gate layer is disposed at a level higher than the first lower gate layer,
wherein a lower end of the second lower gate contact structure is disposed at a level higher than a lower end of the first lower gate contact structure,
wherein a side surface of the second lower gate contact structure comprises a second contact bending portion, bent from a side surface of the second upper contact portion and extending to a side surface of the second lower contact portion, and
wherein the first contact bending portion and the second contact bending portion are disposed at substantially the same level.

6. The semiconductor device of claim 5,
wherein the side surface of the first lower contact portion comprises N first lower bending portions,
wherein the side surface of the second lower contact portion comprises M second lower bending portions,
wherein N is a natural number, M is 0 or a natural number, and N is greater than M.

7. The semiconductor device of claim 6, further comprising:
a separation structure penetrating the stack structure in the vertical direction, wherein the separation structure has a line shape extending in a first horizontal direction perpendicular to the vertical direction,
wherein the separation structure comprises an upper separation portion penetrating the upper stack region and a lower separation portion extending from the upper separation portion and penetrating the lower stack region,
wherein a side surface of the separation structure comprises a separation bending portion, bent from a side surface of the upper separation portion and extending to a side surface of the lower separation portion,
wherein at least a portion of the separation bending portion is disposed at substantially the same level as at least a portion of the first contact bending portion, and
wherein the side surface of the lower separation portion comprises K lower separation bending portions, K being a natural number equal to or greater than N.

8. The semiconductor device of claim 5,
wherein the side surface of the first lower contact portion comprises a first lower bending portion and a second lower bending portion disposed at a level higher than the first lower bending portion and disposed at a level lower than the first contact bending portion, and
wherein the side surface of the second lower contact portion comprises a third lower bending portion disposed at substantially the same level as the second lower bending portion.

9. The semiconductor device of claim 1,
wherein the side surface of the first upper contact portion does not have a bending portion at a level lower than a lower surface of an uppermost upper gate layer of the plurality of upper gate layers.

10. The semiconductor device of claim 9,
wherein the side surface of the first upper contact portion comprises an upper bending portion, bent at a level higher than the lower surface of the uppermost upper gate layer.

11. The semiconductor device of claim 1,
wherein the lower stack region comprises a first lower stack region and a second lower stack region on the first lower stack region,
wherein the upper stack region comprises a first upper stack region and a second upper stack region on the first upper stack region,
wherein the lower channel portion of the vertical channel structure comprises:
a first lower channel portion penetrating the first lower stack region; and
a second lower channel portion extending from the first lower channel portion and penetrating the second lower stack region;
wherein the upper channel portion of the vertical channel structure comprises:
a first upper channel portion penetrating the first upper stack region; and
a second upper channel portion extending from the first upper channel portion and penetrating the second upper stack region,
wherein the side surface of the lower channel portion comprises a lower channel bending portion, bent from a side surface of the second lower channel portion and extending to a side surface of the first lower channel portion, and
wherein the side surface of the upper channel portion comprises an upper channel bending portion, bent from a side surface of the second upper channel portion and extending to a side surface of the first upper channel portion.

12. The semiconductor device of claim 11,
wherein the side surface of the first upper contact portion of the first lower gate contact structure does not have a bending portion at the same level as the upper channel bending portion.

13. The semiconductor device of claim 1, further comprising
a vertical support structure penetrating the stack structure and adjacent to at least one of the plurality of lower and upper gate contact structures,
wherein the vertical support structure comprises a vertical pillar vertically penetrating the stack structure and a plurality of horizontal protrusions extending from a side surface of the vertical pillar into the plurality of lower and upper gate layers, and
wherein the vertical support structure does not comprise a material of the channel layer.

14. The semiconductor device of claim 1,
wherein the conductive contact plug of the first lower gate contact structure contacts the first lower gate layer, and
wherein a lower end of the insulating spacer of the first lower gate contact structure is disposed at a level higher than an upper surface of the first lower gate layer and spaced apart from the upper surface of the first lower gate layer.

15. The semiconductor device of claim 1, further comprising:
an interconnection structure disposed on the stack structure and comprising a plurality of first bonding pads; and
a peripheral circuit structure vertically overlapping the stack structure and comprising a plurality of second bonding pads bonded to the plurality of first bonding pads.

16. A semiconductor device, comprising:
a stack structure comprising a lower stack region and an upper stack region on the lower stack region, wherein the lower stack region comprises a plurality of lower gate layers and a plurality of lower interlayer insulating layers stacked in a vertical direction, and the upper stack region comprises a plurality of upper gate layers and a plurality of upper interlayer insulating layers stacked in the vertical direction;
a separation structure penetrating the stack structure in the vertical direction, wherein the separation structure has a line shape extending in a first horizontal direction perpendicular to the vertical direction;
a vertical channel structure penetrating the stack structure in the vertical direction and comprising a data storage structure and a channel layer;
a plurality of lower gate contact structures contacting a plurality of lower gate contact regions of the lower gate layers, wherein the plurality of lower gate contact structures extend vertically and penetrate the upper stack region; and
a plurality of upper gate contact structures contacting a plurality of upper gate contact regions of the plurality of upper gate layers,
wherein the plurality of upper gate contact structures extend vertically,
wherein each of the plurality of lower and upper gate contact structures comprises a conductive contact plug and an insulating spacer on a side surface of the conductive contact plug,
wherein, in each of the plurality of lower gate contact structures, the conductive contact plug contacts a corresponding lower gate contact region of the plurality of lower gate contact regions,
wherein, in each of the plurality of upper gate contact structures, the conductive contact plug contacts a corresponding upper gate contact region of the plurality of upper gate contact regions,
wherein a first lower gate contact structure of the plurality of lower gate contact structures comprises a first upper contact portion penetrating the upper stack region, and a first lower contact portion extending downwardly from the first upper contact portion and contacting a first lower gate layer of the plurality of lower gate layers,
wherein a side surface of the first lower gate contact structure comprises a first contact bending portion, bent from a side surface of the first upper contact portion and extending to a side surface of the first lower contact portion,
wherein the separation structure comprises an upper separation portion penetrating the upper stack region and a lower separation portion extending from the upper separation portion and penetrating the lower stack region,
wherein a side surface of the separation structure comprises a separation bending portion, bent from a side surface of the upper separation portion and extending to a side surface of the lower separation portion, and
wherein at least a portion of the separation bending portion is disposed at substantially the same level as at least a portion of the first contact bending portion.

17. The semiconductor device of claim 16,
wherein the vertical channel structure comprises an upper channel portion penetrating the upper stack region, and a lower channel portion extending from the upper channel portion and penetrating the lower stack region,
wherein at a height level between a lowermost lower gate layer of the lower gate layers and an uppermost upper gate layer of the upper gate layers, a side surface of the vertical channel structure comprises X channel bending portions, and a side surface of the first lower gate contact structure comprises Y contact bending portions, and
wherein X and Y are natural numbers greater than 2.

18. The semiconductor device of claim 16,
wherein the side surface of the vertical channel structure comprises a first channel bending portion, a second channel bending portion, and a third channel bending portion, which are disposed at different levels from each other,
wherein the side surface of the first lower gate contact structure further comprises a second contact bending portion and a third contact bending portion,
wherein the first contact bending portion, the second contact bending portion, and the third contact bending portion are disposed at different levels from each other,
wherein the at least a portion of the first contact bending portion is disposed at the same level as at least a portion of the second channel bending portion,
wherein the first channel bending portion is disposed at a level lower than the second channel bending portion,
wherein the third channel bending portion is disposed at a level higher than the second channel bending portion,
wherein the second contact bending portion and the third contact bending portion are disposed at levels lower than the first contact bending portion, and
wherein at least one of the second contact bending portion and the third contact bending portion is disposed at a different level from the first channel bending portion.

19. A data storage system comprising:
a semiconductor device comprising an input/output pad; and
a controller electrically connected to the semiconductor device via the input/output pad and controlling the semiconductor device,
wherein the semiconductor device, comprising:
a stack structure comprising a lower stack region and an upper stack region on the lower stack region, wherein the lower stack region comprises a plurality of lower gate layers and a plurality of lower interlayer insulating layers alternately stacked in a vertical direction, and the upper stack region comprises a plurality of upper gate layers and a plurality of upper interlayer insulating layers alternately stacked in the vertical direction;
a separation structure penetrating the stack structure in the vertical direction, wherein the separation structure has a line shape extending in a first horizontal direction perpendicular to the vertical direction;
a vertical channel structure penetrating the stack structure in the vertical direction and comprising a data storage structure and a channel layer;
a plurality of lower gate contact structures contacting a plurality of lower gate contact regions of the plurality of lower gate layers, wherein the plurality of lower gate contact structures extend vertically and penetrate the upper stack region; and
a plurality of upper gate contact structures contacting a plurality of upper gate contact regions of the plurality of upper gate layers,
wherein the plurality of upper gate contact structures extend vertically,
wherein each of the plurality of lower and upper gate contact structures comprises a conductive contact plug and an insulating spacer on a side surface of the conductive contact plug,
wherein a first lower gate contact structure of the plurality of lower gate contact structures comprises a first upper contact portion penetrating the upper stack region, and a first lower contact portion extending downwardly from the first upper contact portion and contacting a first lower gate layer of the plurality of lower gate layers,
wherein a side surface of the first lower gate contact structure comprises a first contact bending portion, bent from a side surface of the first upper contact portion and extending to a side surface of the first lower contact portion,
wherein the vertical channel structure comprises an upper channel portion penetrating the upper stack region, and a lower channel portion extending from the upper channel portion and penetrating the lower stack region,
wherein a side surface of the vertical channel structure comprises a channel bending portion, bent from a side surface of the upper channel portion and extending to a side surface of the lower channel portion, and
wherein at least a portion of the channel bending portion is disposed at the same level as at least a portion of the first contact bending portion.

20. The data storage system of claim 19,
wherein the plurality of upper gate layers surround a side surface of the first lower gate contact structure,
wherein, among the plurality of lower gate layers, a lower gate layer disposed at a level higher than the first lower gate layer surrounds the side surface of the first lower gate contact structure,
wherein the separation structure comprises an upper separation portion penetrating the upper stack region and a lower separation portion extending from the upper separation portion and penetrating the lower stack region,
wherein a side surface of the separation structure comprises a separation bending portion, bent from a side surface of the upper separation portion and extending to a side surface of the lower separation portion, and
wherein at least a portion of the separation bending portion is disposed at substantially the same level as the at least a portion of the first contact bending portion.
